(19) United States
(12) Patent Application Publication
(10) Pub. No.: US 2025/0100019 A1
(43) Pub. Date: Mar. 27, 2025

(54) SUBSTRATE PROCESSING APPARATUS

(71) Applicant: SCREEN HOLDINGS CO., LTD., Kyoto (JP)

(72) Inventors: Kazuma FUNAHASHI, Kyoto-shi (JP); Tomoyuki SHINOHARA, Kyoto-shi (JP)

(73) Assignee: SCREEN HOLDINGS CO., LTD., Kyoto (JP)

(21) Appl. No.: 18/889,420

(22) Filed: Sep. 19, 2024

(30) Foreign Application Priority Data
Sep. 22, 2023 (JP) 2023-159237

(51) Int. Cl. B08B 1/52; B08B 13/00

(52) U.S. Cl. CPC B08B 1/52; B08B 13/00

(57) ABSTRACT

A substrate processing apparatus includes a substrate holding device, a brush arm, a plurality of brush devices, a brush storage device, and a brush liquid supply system. The tip portion of the brush arm is configured as a brush holder to which the brush device can be attached and detached. A substrate held by the substrate holding device is cleaned with the brush device. The brush storage device stores unprocessed brush devices. The used brush device is removed from the brush holder. An unprocessed brush device stored in the brush storage device is attached to the brush holder. The brush storage device is configured so that a cleaning surface of the stored brush device is maintained in a state of being wetted with a processing liquid supplied from the brush liquid supply system.

### CROSS-REFERENCE TO RELATED APPLICATION

This application claims the priority benefits of Japanese application no. 2023-159237, filed on Sep. 22, 2023. The entirety of the above-mentioned patent application is hereby incorporated by reference herein and made a part of this specification.

### BACKGROUND

### Technical Field

The disclosure relates to a substrate processing apparatus that cleans a substrate by bringing a cleaning tool into contact with the substrate.

### Description of Related Art

A substrate processing apparatus has been used to perform various types of processing on substrates such as a FPD (Flat Panel Display) substrate for a liquid crystal display device or an organic EL (Electro Luminescence) display device, an optical disk substrate, a magnetic disk substrate, a magneto-optical disk substrate, a photomask substrate, a ceramic substrate, and a solar cell substrate.

As an example of the substrate processing apparatus, JP 08-318226 A describes a scrubber cleaning apparatus that cleans a wafer (substrate) using a brush. The scrubber cleaning apparatus has a brush and an arm. The tip portion of the arm is configured so that the brush can be attached thereto or detached therefrom. The brush attached to the tip portion of the arm is moved to a cleaning position and slid on the substrate. Thereby, the substrate is cleaned.

The brush used for cleaning will become contaminated or worn depending on the conditions of use. A brush that is overly contaminated or worn may not be able to appropriately clean a substrate. Thus, in the above-described scrubber cleaning apparatus, a brush holding frame is provided at a retracted position different from the cleaning position.

The brush holding frame holds a plurality of brushes. Thus, when one brush attached to the tip portion of the arm needs to be replaced, the brush is moved to the retracted position and removed from the tip portion of the arm. Then, another brush held by the brush holding frame is attached to the tip portion of the arm. In this manner, the brush used to clean the substrate is replaced.

Depending on the substrate to be processed, the brush used for cleaning may need to be pre-wetted. In this case, in the scrubber cleaning apparatus of JP8-318226, after replacing the brush attached to the tip portion of the arm, the new brush has to be wetted to a certain degree to be usable for cleaning. Such brush pre-processing work reduces the operating efficiency of the scrubber cleaning apparatus.

The disclosure provides a substrate processing apparatus that is capable of shortening the time required from replacement of a cleaning tool to resumption of a cleaning process using the cleaning tool.

### SUMMARY

A substrate processing apparatus according to one aspect of the disclosure includes: a substrate holder holding a substrate; a first cleaning tool and a second cleaning tool each having a connected portion and a cleaning surface; a cleaning tool holder including a connecting portion that is attachable to and detachable from the connected portions of the first cleaning tool and the second cleaning tool, and respectively holding the first cleaning tool and the second cleaning tool by connecting the connecting portion to the connected portion; a cleaning tool storage part provided at a position spaced apart from the substrate held by the substrate holder and temporarily storing the second cleaning tool in a state where the first cleaning tool is held by the cleaning tool holder; a cleaning tool holder moving device moving the cleaning tool holder so that the cleaning surface of the first cleaning tool or the second cleaning tool held by the cleaning tool holder comes into contact with the substrate, and moving the cleaning tool holder to the cleaning tool storage part; a processing liquid supply part supplying a predetermined processing liquid to the cleaning tool storage part; and a controller, in which the controller controls the cleaning tool holder moving device in a state where the cleaning tool holder holds the first cleaning tool, to clean the substrate held by the substrate holder, and after the first cleaning tool used for cleaning the substrate is removed from the cleaning tool holder, controls the cleaning tool holder moving device to connect the connecting portion of the cleaning tool holder to the connected portion of the second cleaning tool temporarily stored in the cleaning tool storage part, and the cleaning tool storage part is configured to maintain the cleaning surface of the second cleaning tool temporarily stored in a state of being wetted with the processing liquid supplied from the processing liquid supply part.

According to the disclosure, it is possible to shorten the time required from replacement of a cleaning tool to resumption of a cleaning process using the cleaning tool.

Other features, elements, characteristics, and advantages of the present disclosure will become more apparent from the following description of preferred embodiments of the present disclosure with reference to the attached drawings.

### BRIEF DESCRIPTION OF THE DRAWINGS

FIG. 1 is a schematic plan view of the substrate processing apparatus according to an embodiment of the disclosure.

FIG. 2A and FIG. 2B are views for illustrating the basic operation during the substrate cleaning process in the substrate processing apparatus of FIG. 1.

FIG. 3A and FIG. 3B are views for illustrating the basic operation during the brush device replacement process in the substrate processing apparatus of FIG. 1.

FIG. 4A and FIG. 4B are views for illustrating the basic operation during the brush device replacement process in the substrate processing apparatus of FIG. 1.

FIG. 5A and FIG. 5B are views for illustrating the basic operation during the brush device replacement process in the substrate processing apparatus of FIG. 1.

FIG. 6 is an external perspective view of the brush device.

FIG. 7 is a vertical cross-sectional view of the brush device of FIG. 6.

FIG. 8 is an external perspective view of the brush device connecting portion.

FIG. 9 is a vertical cross-sectional view of the brush device connecting portion of FIG. 8.

FIG. 10A and FIG. 10B are external perspective views for illustrating the operation when holding the brush device with the brush device connecting portion.

FIG. 11 is a vertical cross-sectional view showing a state where the brush device connecting portion is holding the brush device.

FIG. 12 is a cross-sectional view taken along the line A-A of FIG. 11.

FIG. 13A and FIG. 13B are external perspective views for illustrating the operation when removing the brush device held by the brush device connecting portion.

FIG. 14 is a view for illustrating the configuration of the brush storage device.

FIG. 15 is an external perspective view of the brush storage tank.

FIG. 16A and FIG. 16B are a schematic plan view and a vertical cross-sectional view of the brush storage tank of FIG. 15.

FIG. 17 is an external perspective view of the brush support body.

FIG. 18 is a plan view showing an example of the configuration in which the brush support body is provided to cover a part of the brush storage tank.

FIG. 19A and FIG. 19B are a schematic plan view and a vertical cross-sectional view showing a state where four brush devices are stored in the brush storage tank in the configuration of FIG. 18.

FIG. 20 is a view for illustrating the basic operation of the brush storage device accompanying the brush device replacement process.

FIG. 21 is a view for illustrating the basic operation of the brush storage device accompanying the brush device replacement process.

FIG. 22 is a view for illustrating the basic operation of the brush storage device accompanying the brush device replacement process.

FIG. 23 is a view for illustrating the basic operation of the brush storage device accompanying the brush device replacement process.

FIG. 24 is a view for illustrating the basic operation of the brush storage device accompanying the brush device replacement process.

FIG. 25 is a view for illustrating the basic operation of the brush storage device accompanying the brush device replacement process.

FIG. 26 is a view for illustrating the basic operation of the brush storage device accompanying the brush device replacement process.

FIG. 27 is a block diagram showing the configuration of the control system of the substrate processing apparatus of FIG. 1.

FIG. 28 is a schematic plan view of the substrate processing apparatus according to another embodiment.

FIG. 29 is a schematic plan view of the substrate processing apparatus according to yet another embodiment.

### DESCRIPTION OF THE EMBODIMENTS

Hereinafter, a substrate processing apparatus according to an embodiment of the disclosure will be described with reference to the drawings. In the following description, the term “substrate” refers to a FPD (Flat Panel Display) substrate used in a liquid crystal display device or an organic EL (Electro Luminescence) display device, a semiconductor substrate, an optical disk substrate, a magnetic disk substrate, a magneto-optical disk substrate, a photomask substrate, a ceramic substrate, or a solar cell substrate.

In this embodiment, the substrate has a circular shape in plan view except for a portion where a notch is formed. The substrate has a front surface which is a circuit forming surface, and a back surface which is a surface opposite to the circuit forming surface. In the following description, the surface facing upward of the two surfaces of the substrate is referred to as the upper surface of the substrate, and the surface facing downward of the two surfaces of the substrate is referred to as the lower surface of the substrate, regardless of whether the surface is the front surface or back surface of the substrate.

The substrate processing apparatus described below performs a cleaning process using a brush on a substrate to be processed. During the cleaning process, a predetermined cleaning liquid is supplied to the upper surface of the substrate while the brush is pressed against the upper surface of the substrate. Further, in the substrate processing apparatus described below, a brush replacement process is performed in a case where the brush used for cleaning the substrate becomes contaminated or worn and does not provide an appropriate cleaning power.

### 1. Overall Configuration of the Substrate Processing Apparatus

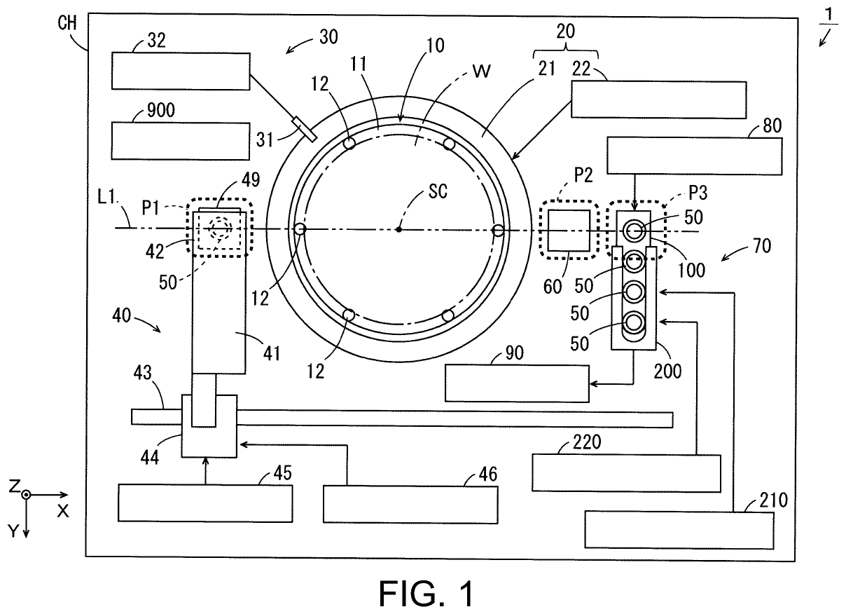

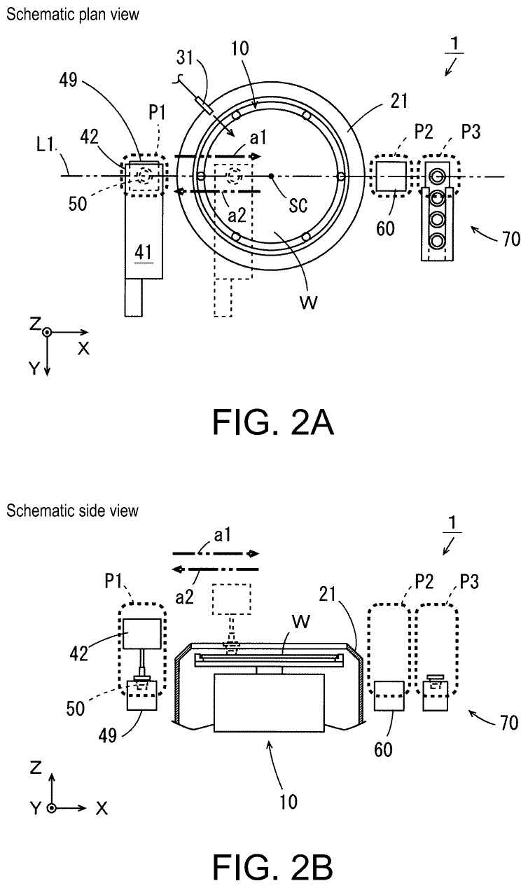

FIG. 1 is a schematic plan view of the substrate processing apparatus according to an embodiment of the disclosure. In FIG. 1 and certain drawings following FIG. 2A and FIG. 2B, arrows are provided to indicate the mutually orthogonal X, Y, and Z directions in order to clarify the positional relationship. The X direction and the Y direction are perpendicular to each other in a horizontal plane, and the Z direction corresponds to the up-down direction (vertical direction).

As shown in FIG. 1, the substrate processing apparatus 1 has a configuration in which a plurality of members are accommodated in a chamber CH, and includes a substrate holding device 10, a cup device 20, a nozzle device 30, a brush arm device 40, a plurality of brush devices 50, a standby pod 49, and a brush disposal part 60. The substrate processing apparatus 1 also includes a brush storage device 70, a brush liquid supply system 80, a brush liquid discharge system 90, and a controller 900.

The chamber CH has four side surfaces, a ceiling surface, and a floor surface (bottom surface). A transfer opening (not shown) for transferring a substrate between the inside of the chamber CH and the outside of the chamber CH is formed on one side surface of the chamber CH.

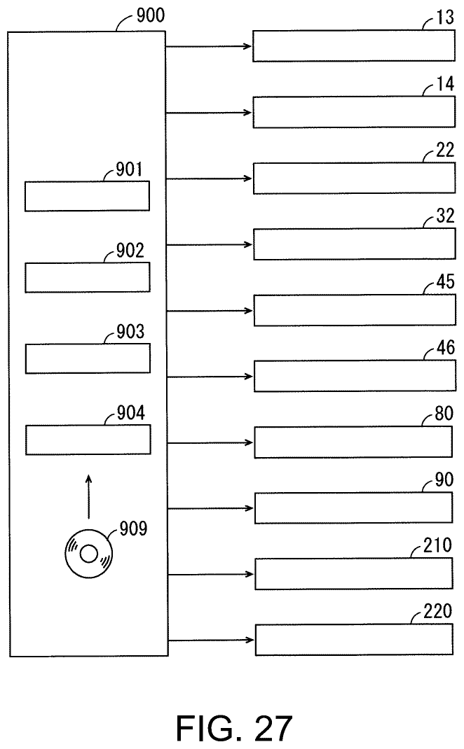

The substrate holding device 10 is provided approximately in the center of the floor surface of the chamber CH. The substrate holding device 10 includes a spin base 11, a plurality of holding pins 12, a substrate holding drive part 13 (FIG. 27), and a substrate rotation drive part 14 (FIG. 27). The substrate rotation drive part 14 is, for example, a motor, and is fixed to the floor surface of the chamber CH with a rotation shaft facing upward. The disk-shaped spin base 11 is attached to the upper end portion of the rotation shaft.

The spin base 11 has an outer diameter larger than the substrate W to be processed. The plurality of holding pins 12 are provided on the peripheral edge portion of the upper surface of the spin base 11. Each of the plurality of holding pins 12 has an abutment portion. Each holding pin 12 is configured to be movable between a holding state where the abutment portion abuts against the outer peripheral end portion of the substrate W and a released state where the abutment portion is separated from the substrate W in a state where the substrate W is disposed on the spin base 11. The substrate holding drive part 13 includes, for example, a magnet, and switches each holding pin 12 between the holding state and the released state using the magnetic force of the magnet. The substrate W is held on the spin base 11 by abutting the abutment portions of the plurality of holding pins 12 in the holding state against a plurality of portions of the outer peripheral end portion of the substrate W. In FIG. 1, the outline of the substrate W held by the substrate holding device 10 is indicated by a one-dot chain line.

The cup device 20 includes a cup body 21 and a cup lifting drive part 22. The cup body 21 has a substantially cylindrical shape, and is provided to surround the spin base 11 in plan view and extend in the Z direction. Moreover, the cup body 21 is provided to be movable in the Z direction.

The cup lifting drive part 22 includes an actuator such as a motor or an air cylinder, and moves the cup body 21 between predetermined cup upper position and cup lower position. The cup upper position is a height position (position in the up-down position) at which the upper end portion of the cup body 21 is above the substrate W held by the substrate holding device 10. The cup lower position is a height position at which the upper end portion of the cup body 21 is below the substrate W held by the substrate holding device 10.

The nozzle device 30 includes a fluid nozzle 31 and a fluid supply system 32. The fluid nozzle 31 is provided at a predetermined position above the substrate holding device 10 and the cup device 20. The fluid nozzle 31 is fixed so that the discharge port thereof faces a rotation center SC of the spin base 11 in the substrate holding device 10. The fluid supply system 32 supplies a cleaning liquid to the fluid nozzle 31 during the cleaning process of the substrate W. Thus, the cleaning liquid is supplied to the upper surface of the substrate W held by the substrate holding device 10. The cleaning liquid is, for example, pure water (deionized water). Instead of pure water, the cleaning liquid may be carbonated water, ozone water, hydrogen water, electrolytic ion water, SC1 (a mixed solution of ammonia and hydrogen peroxide), TMAH (tetramethylammonium hydroxide), or the like. Further, the nozzle device 30 may be configured to be capable of injecting a gas such as an inert gas from the fluid nozzle 31. Furthermore, the nozzle device 30 may have a plurality of fluid nozzles 31 capable of discharging or injecting different fluids.

The brush arm device 40 includes a brush arm 41, a guide rail 43, an arm support part 44, an arm horizontal drive part 45, and an arm lifting drive part 46. In the chamber CH, the guide rail 43 is provided adjacent to the substrate holding device 10 in the Y direction. The guide rail 43 extends in the X direction.

The arm support part 44 is provided to be movable in the X direction along the guide rail 43. The arm horizontal drive part 45 is, for example, a motor, and moves the arm support part 44 in the X direction under the control of the controller 900, which will be described later. The brush arm 41 is supported by the arm support part 44 to be movable in the Z direction. The arm lifting drive part 46 includes an actuator such as a motor or an air cylinder, and moves the brush arm 41 in the Z direction under the control of the controller 900, which will be described later.

The brush arm 41 has a substantially rectangular parallelepiped shape, and is supported to extend in the Y direction from the arm support part 44 toward the substrate holding device 10. The tip portion of the brush arm 41 is configured as a brush holder 42 capable of holding and removing (attaching and detaching) the brush device 50 used for cleaning the substrate W. The brush device 50 will be described in detail later. In the substrate processing apparatus 1 of FIG. 1, the brush holder 42 is positioned on an imaginary straight line L1 that passes through the rotation center SC of the spin base 11 in plan view and extends in the X direction.

In plan view, in addition to the substrate holding device 10, the standby pod 49, the brush disposal part 60, and the brush storage device 70 are aligned on the imaginary straight line L1. Specifically, the standby pod 49, the substrate holding device 10, the brush disposal part 60, and the brush storage device 70 are arranged in this order on the imaginary straight line L1.

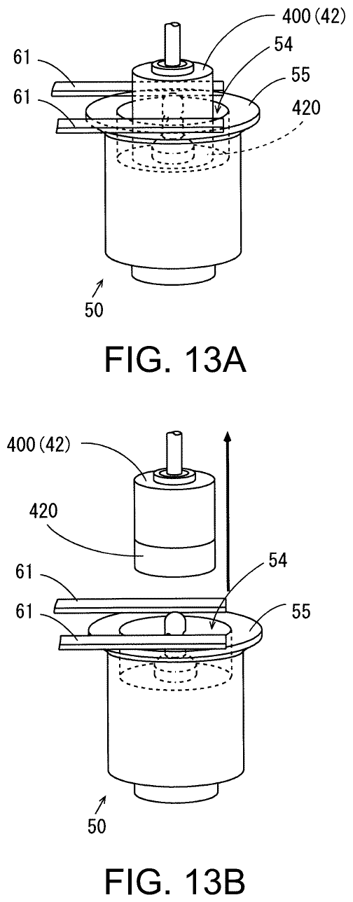

The standby pod 49 is configured to be capable of accommodating the brush device 50 held by the brush holder 42 in a clean state and cleaning. The brush disposal part 60 has a removal structure 61 (FIG. 13A and FIG. 13B), which will be described later, for removing the brush device 50 held by the brush holder 42 from the brush holder 42, and is configured to be capable of accommodating the removed brush device 50. The brush storage device 70 is configured to be capable of storing a plurality of unused brush devices 50.

Here, the brush storage device 70 includes a brush storage tank 100, a brush support body 200, a storage brush horizontal drive part 210, and a storage brush lifting drive part 220. The brush storage tank 100 is configured to be capable of storing a plurality of unused brush devices 50. A predetermined processing liquid is supplied from the brush liquid supply system 80 to the brush storage tank 100 and stored therein. The brush device 50 has a cleaning surface for cleaning the substrate W. The processing liquid supplied to the brush storage tank 100 is used to wet the cleaning surface of the unused brush device 50 stored in the brush storage tank 100. In the following description, this processing liquid will be referred to as a brush liquid. The brush liquid may be a cleaning liquid used to clean the substrate W. In this embodiment, the brush liquid is pure water. A part of the brush liquid stored in the brush storage tank 100 is discharged to the outside of the substrate processing apparatus 1 (for example, to an exhaust facility or the like) through the brush liquid discharge system 90.

The storage brush horizontal drive part 210 and the storage brush lifting drive part 220 operate to change the storage position of one or more brush devices 50 stored in the brush storage tank 100. The configurations and operations of the storage brush horizontal drive part 210 and the storage brush lifting drive part 220 will be described in detail later. The controller 900 controls the operation of each part of the substrate processing apparatus 1. The controller 900 will be described in detail later.

As indicated by a thick dotted line frame in FIG. 1, in the substrate processing apparatus 1, a standby position P1 is set at a position overlapping the standby pod 49 in plan view. Further, a removal position P2 is set at a position overlapping the brush disposal part 60 in plan view. Furthermore, an attachment position P3 is set at a position overlapping a part of the brush storage tank 100 in plan view. The standby position P1, the removal position P2, and the attachment position P3 are aligned on the imaginary straight line L1.

### 2. Various Basic Operations in the Substrate Processing Apparatus

(a) FIG. 2A and FIG. 2B are views for illustrating the basic operation during the cleaning process of the substrate W in the substrate processing apparatus 1 of FIG. 1. A schematic plan view of the substrate processing apparatus 1 is shown in FIG. 2A, and a schematic side view of the substrate processing apparatus 1 is shown in FIG. 2B.

In the initial state of the cleaning process of the substrate W, the brush holder 42 that holds the brush device 50 is located at the standby position P1. The brush device 50 is accommodated in the standby pod 49. Additionally, the cup body 21 is at the cup lower position, and the discharge of the cleaning liquid from the fluid nozzle 31 is stopped.

When the cleaning process of the substrate W is started, the substrate W is carried into the substrate processing apparatus 1 is held by the substrate holding device 10 and rotated at a predetermined rotation speed. Further, the cup body 21 is held at the cup upper position. Furthermore, the cleaning liquid is discharged from the fluid nozzle 31 toward the substrate W that is rotating.

In this state, the arm horizontal drive part 45 and the arm lifting drive part 46 shown in FIG. 1 operate to move the brush arm 41 in the Z direction and the X direction. Thus, the brush device 50 held by the brush holder 42 is pulled up from the standby pod 49 and pressed against the upper surface of the substrate W that is rotating. In this state, as indicated by thick two-dot chain line arrows a1 and a2 in FIG. 2A and FIG. 2B, the brush device 50 is moved in the X direction along the imaginary straight line L1 in plan view. In this manner, the upper surface of the substrate W is cleaned.

Once the upper surface of the substrate W is cleaned, the brush device 50 is returned to the position in the initial state. Further, the discharge of the cleaning liquid from the fluid nozzle 31 is stopped, and the rotation of the substrate W performed by the substrate holding device 10 is stopped. Furthermore, the cup body 21 moves from the cup upper position to the cup lower position. Thereby, the cleaning process of the substrate W is completed.

In the example of FIG. 2A and FIG. 2B, the brush device 50 reciprocates between the outer peripheral end portion of the substrate W and the rotation center SC of the spin base 11, but the substrate W may be cleaned by moving the brush device 50 from one end portion to the other end portion of the substrate W along the imaginary straight line L1. Alternatively, the brush device 50 may clean the substrate W by moving once between the outer peripheral end portion of the substrate W and the rotation center SC of the spin base 11.

(b) As described above, in the substrate processing apparatus 1 according to this embodiment, the brush replacement process is performed to replace the brush used for cleaning the substrate W. Here, the brush device 50 has a configuration in which a brush and a plurality of members accompanying the brush are integrally assembled. Therefore, in the substrate processing apparatus 1, a process is performed as the brush replacement process to replace the used brush device 50 (old brush device 50) held by the brush holder 42 with an unused brush device 50 (new brush device 50).

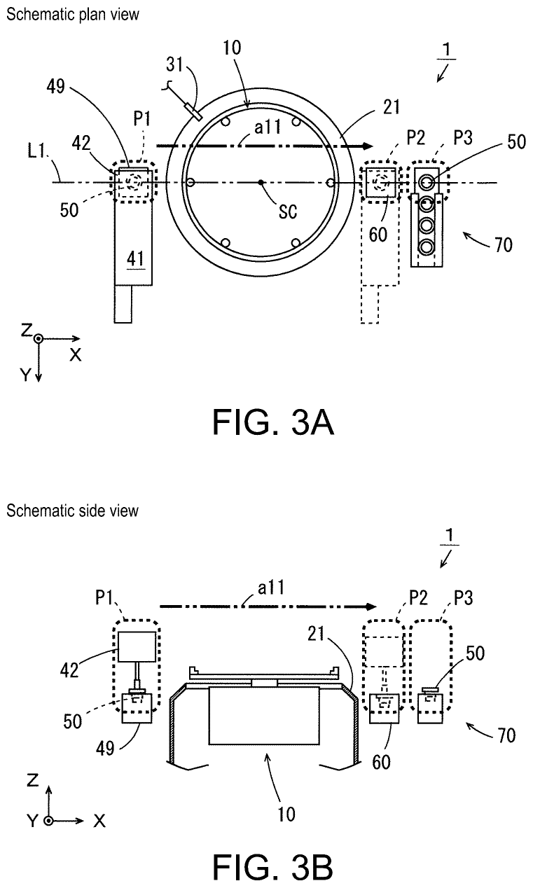

FIG. 3A and FIG. 3B to FIG. 5A and FIG. 5B are views for illustrating the basic operation during the replacement process of the brush device 50 in the substrate processing apparatus 1 of FIG. 1. Similar to the example of FIG. 2A and FIG. 2B, a schematic plan view of the substrate processing apparatus 1 is shown in FIG. 3A to FIG. 5A, and a schematic side view of the substrate processing apparatus 1 is shown in FIG. 3B to FIG. 5B.

In the initial state of the replacement process of the brush device 50, as shown in FIG. 3A and FIG. 3B, the brush holder 42 that holds the old brush device 50 is located at the standby position P1. The brush device 50 is accommodated in the standby pod 49. Additionally, the cup body 21 is at the cup lower position, and the discharge of the cleaning liquid from the fluid nozzle 31 is stopped. Furthermore, the unused brush devices 50 are stored in the brush storage tank 100 of the brush storage device 70.

When the replacement process of the brush device 50 is started, the arm horizontal drive part 45 and the arm lifting drive part 46 shown in FIG. 1 operate to move the brush arm 41 in the Z direction and the X direction. Thus, the brush device 50 held by the brush holder 42 is pulled up from the standby pod 49. Further, as indicated by a thick two-dot chain line arrow a11 in FIG. 3A and FIG. 3B, the brush holder 42 moves in the space above the substrate holding device 10 to the removal position P2.

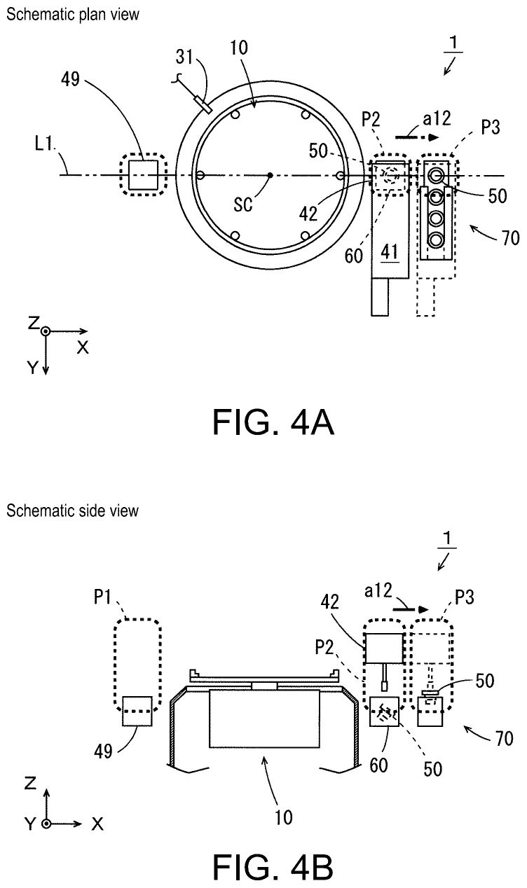

At the removal position P2, the used brush device 50 is removed from the brush holder 42 and accommodated in the brush disposal part 60. Thereafter, as indicated by a thick two-dot chain line arrow a12 in FIG. 4A and FIG. 4B, the brush holder 42 in a state of not holding a brush device 50 moves from the removal position P2 to the attachment position P3.

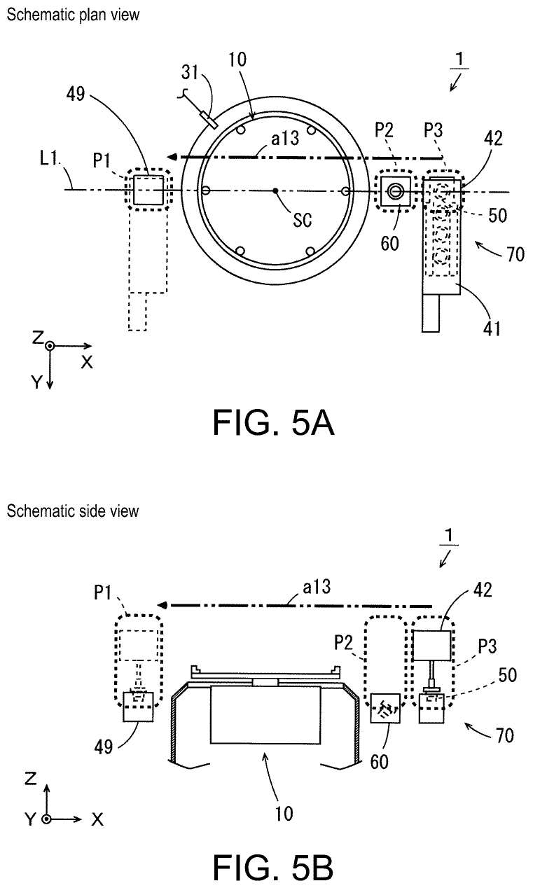

At the attachment position P3, an unused brush device 50 stored in the brush storage tank 100 is held by the brush holder 42. Further, the brush device 50 held by the brush holder 42 is pulled up from the brush storage tank 100. Thereafter, as indicated by a thick two-dot chain line arrow a13 in FIG. 5B, the brush holder 42 passes through the space above the substrate holding device 10 and moves to the standby position P1. Then, the brush device 50 held by the brush holder 42 is accommodated in the standby pod 49. Thereby, the replacement process of the brush device 50 is completed.

### 3. Configuration of the Brush Device 50

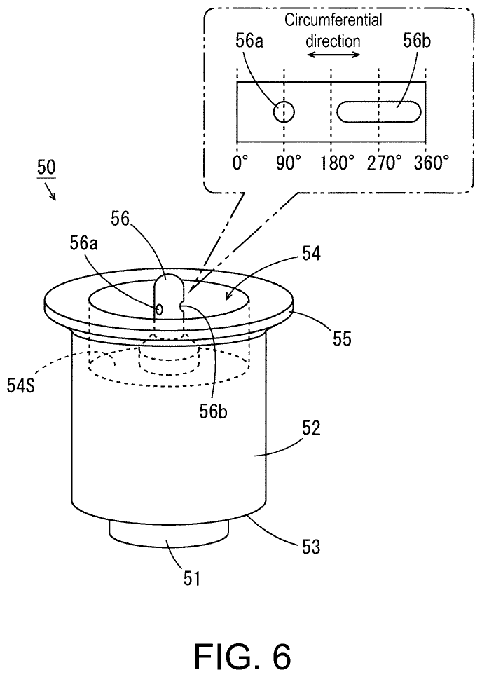

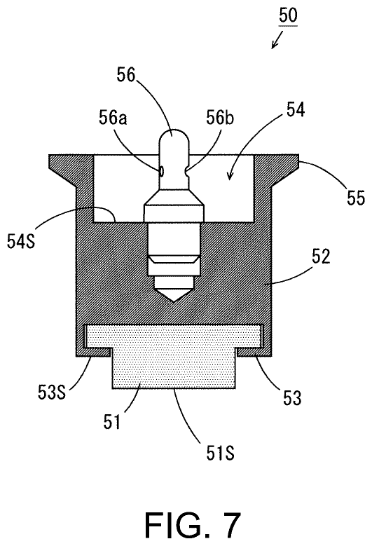

FIG. 6 is an external perspective view of the brush device 50, and FIG. 7 is a vertical cross-sectional view of the brush device 50 of FIG. 6. As shown in FIG. 6, the brush device 50 includes a brush 51, a brush support body 52, and a connected post 56. The brush support body 52 has a substantially columnar shape and has a brush attachment portion 53 at the lower end portion.

The brush 51 is formed, for example, from a PVA (polyvinyl alcohol) sponge or a PVA sponge with abrasive grains dispersed therein, and has a circular cleaning surface 51S (FIG. 7) capable of coming into contact with the upper surface of the substrate W. As shown in FIG. 7, the brush 51 is attached to the brush attachment portion 53 of the brush support body 52 with the cleaning surface 51S facing downward. The brush attachment portion 53 has an annular supported surface 53S which surrounds a part of the brush 51 while the brush 51 is attached thereto, and is positioned a small distance above the cleaning surface 51S.

As shown in FIG. 6, a recess 54 is formed in the center of the upper end portion of the brush support body 52. Further, an annular flange portion 55 is formed at the upper end portion of the brush support body 52 to surround the recess 54 and protrude outward a fixed distance around the entire periphery of the brush support body 52.

The recess 54 has a flat bottom surface 54S. A screw hole is formed in the central portion of the bottom surface 54S. The connected post 56 is a rod-shaped member having a circular cross section, and has a first groove 56a and a second groove 56b formed in the upper half thereof. Further, a male screw is formed on the lower half of the connected post 56 corresponding to the screw hole in the bottom surface 54S. The lower half of the connected post 56 is attached to the screw hole in the bottom surface 54S. Thus, the upper half of the connected post 56 is fixed to the brush support body 52 in a state where the connected post 56 protrudes upward from the bottom surface 54S of the recess 54.

The upper end portion of the connected post 56 is formed in a semi-spherical shape. The first groove 56a and the second groove 56b are formed at positions spaced a common distance from the upper end portion of the connected post 56 in the axial direction thereof. Moreover, the first groove 56a and the second groove 56b are formed at different positions in the circumferential direction of the connected post 56.

In FIG. 6, a view of the outer peripheral surface of the upper half of the connected post 56 expanded in the circumferential direction is shown within a two-dot chain line bubble. In the expanded view, the angular positions in the circumferential direction based on the central axis of the connected post 56 are indicated in 90° increments from 0° to 360°. As shown in the expanded view, the angular range in the circumferential direction in which the second groove 56b is formed (approximately) 160° is wider than the angular range in the circumferential direction in which the first groove 56a is formed (approximately) 45°.

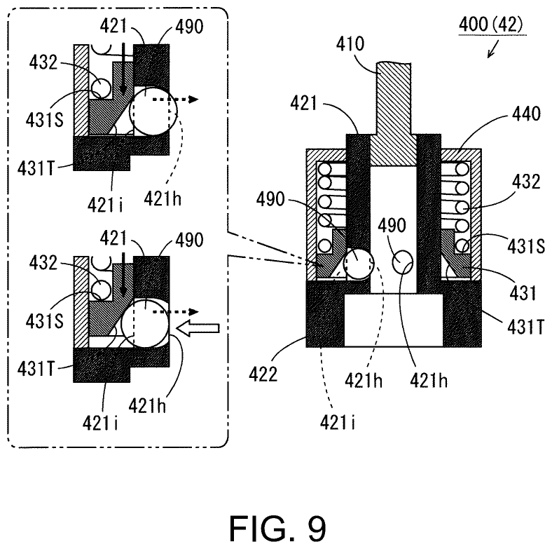

Each of the first groove 56a and the second groove 56b is formed to be capable of accommodating a part of a steel ball 490 (FIG. 9) which will be described later, but not capable of accommodating the entire steel ball 490. Furthermore, the second groove 56b allows the steel ball 490 to move in the circumferential direction within a certain angular range in a state where a part of the steel ball 490 is accommodated therein.

### 4. Configuration of the Brush Holder 42

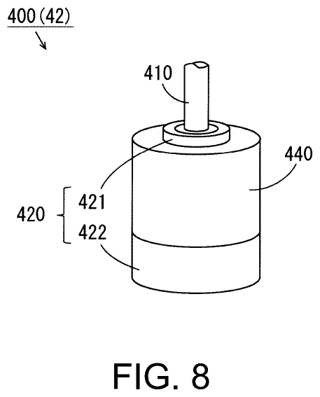

The brush holder 42 of FIG. 1 includes a brush device connecting portion provided at the tip portion of the brush arm 41 to extend in the Z direction (extend downward). FIG. 8 is an external perspective view of the brush device connecting portion, and FIG. 9 is a vertical cross-sectional view of the brush device connecting portion 400 of FIG. 8. As shown in FIG. 8, the brush device connecting portion 400 includes a shaft member 410, a connecting body portion 420, and a casing 440. As shown in FIG. 9, the brush device connecting portion 400 further includes a pressing member 431, a spring 432, and a plurality of steel balls 490 (three in this example).

The connecting body portion 420 has a configuration in which a first cylindrical portion 421 and a second cylindrical portion 422 having different inner and outer diameters are connected in the axial direction. The first cylindrical portion 421 and the second cylindrical portion 422 are arranged vertically in this order. The inner diameter of the first cylindrical portion 421 is slightly larger than the outer diameter of the connected post 56 of the brush device 50. In addition, the inner diameter of the second cylindrical portion 422 is larger than the inner diameter of the first cylindrical portion 421, and the outer diameter of the second cylindrical portion 422 is larger than the outer diameter of the first cylindrical portion 421.

The shaft member 410 is held at the tip portion of the brush arm 41 to be rotatable around the axis of the shaft member 410 by a rotation drive mechanism (not shown). The lower end portion of the shaft member 410 is connected to the upper end portion of the first cylindrical portion 421 and a portion in the vicinity of the upper end portion in a state of being inserted into the first cylindrical portion 421 from above. Thus, the connecting body portion 420 is supported by the shaft member 410.

A plurality of (three in this example) through holes are formed in the vicinity of the lower end portion of the first cylindrical portion 421 and are arranged at equal angular intervals in the circumferential direction. The openings of the through holes formed in the inner peripheral surface of the first cylindrical portion 421 are referred to as inner openings 421h. The openings of the through holes formed in the outer peripheral surface of the first cylindrical portion 421 are referred to as outer openings 421i. The inner opening 421h and the outer opening 421i both have a circular shape.

A part of the steel ball 490 is accommodated inside each through hole. The thickness of the first cylindrical portion 421 is smaller than the diameter of the steel ball 490. Moreover, the inner diameter of the inner opening 421h is smaller than the diameter of the steel ball 490. On the other hand, the inner diameter of the outer opening 421i is larger than the diameter of the steel ball 490. With such a configuration, in a state where a part of the steel ball 490 is accommodated in the through hole of the first cylindrical portion 421, the remaining part is located on at least one of the outside of the first cylindrical portion 421 and the inside of the first cylindrical portion 421.

The cylindrical pressing member 431 having an inner diameter slightly larger than the outer diameter of the first cylindrical portion 421 and an outer diameter smaller than the outer diameter of the second cylindrical portion 422 is fitted into the first cylindrical portion 421. The lower half of the inner peripheral surface of the pressing member 431 is inclined with respect to the axial direction of the pressing member 431 so that the inner diameter gradually increases downward. The inner peripheral surface of the inclined pressing member 431 serves as a ball pressing surface 431T and abuts against parts of three steel balls 490 respectively protruding outward from the three through holes of the first cylindrical portion 421.

The pressing member 431 has an annular pressed surface 431S facing upward. The spring 432 is provided on the pressed surface 431S. The spring 432 in this example is a coil spring, and surrounds the first cylindrical portion 421. The casing 440 is provided around the first cylindrical portion 421 to cover the pressing member 431 and the spring 432. The casing 440 is attached to the connecting body portion 420 to compress the spring 432 from above toward the pressed surface 431S of the pressing member 431. Thus, a pressing force from the spring 432 acts on the pressing member 431 toward the second cylindrical portion 422.

As described above, the ball pressing surface 431T of the pressing member 431 abuts against parts of the three steel balls 490 protruding outward from the three through holes of the first cylindrical portion 421. Therefore, the pressing force applied to the pressing member 431 by the spring 432 acts to press each of the three steel balls 490 toward the axis of the first cylindrical portion 421. In other words, the pressing force along the axis of the first cylindrical portion 421 is converted into a pressing force that presses the three steel balls 490 toward the axis of the first cylindrical portion 421.

Thus, as shown in the upper part of a two-dot chain line bubble in FIG. 9, in a case where no force is applied to each steel ball 490 from inside the first cylindrical portion 421, a part of the steel ball 490 protrudes into the first cylindrical portion 421 from the inner opening 421h. On the other hand, as shown in the lower part of the bubble in FIG. 9, a case is assumed in which a force acting from the inside of the first cylindrical portion 421 toward the outside of the first cylindrical portion 421 acts on each steel ball 490. In this case, as indicated by the hollow arrow, when the force acting from the inside of the first cylindrical portion 421 toward the outside of the first cylindrical portion 421 exceeds the force pressing the steel ball 490 toward the inside of the first cylindrical portion 421 due to the elastic force of the spring 432, the steel ball 490 is pushed out from the internal space of the first cylindrical portion 421.

### 5. Holding and Removal of the Brush Device 50 by the Brush Device Connecting Portion 400

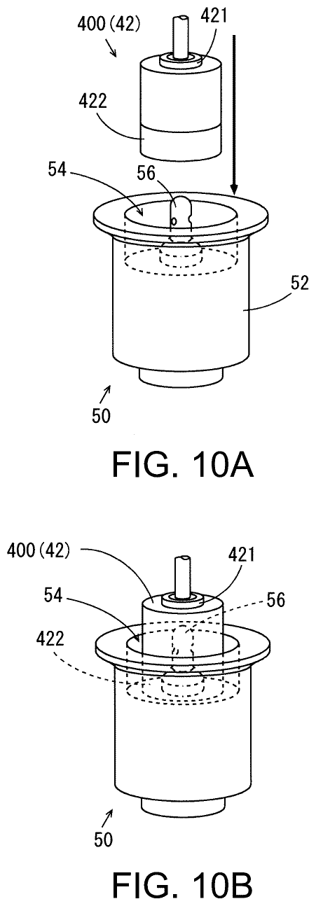

FIG. 10A and FIG. 10B are external perspective views for illustrating the operation when holding the brush device 50 with the brush device connecting portion 400. As shown in FIG. 10A, when holding the brush device 50 with the brush device connecting portion 400, the second cylindrical portion 422 of the brush device connecting portion 400 is pressed into the recess 54 of the brush device 50 shown in FIG. 6. Thus, the brush device 50 is held by the brush device connecting portion 400, as shown in FIG. 10B.

When the second cylindrical portion 422 is pressed in, the connected post 56 of the brush device 50 is inserted into the first cylindrical portion 421 of the brush device connecting portion 400. At this time, inside the first cylindrical portion 421, the parts of the three steel balls 490 protruding into the first cylindrical portion 421 are gradually pressed toward the outside of the first cylindrical portion 421 by the upper end portion of the connected post 56. Thereafter, the connected post 56 advances further into the first cylindrical portion 421, and the lower end portion of the second cylindrical portion 422 abuts against the bottom surface 54S of the recess 54 of the brush device 50. In this state, parts of the three steel balls 490 fit into the first groove 56a and the second groove 56b of the connected post 56.

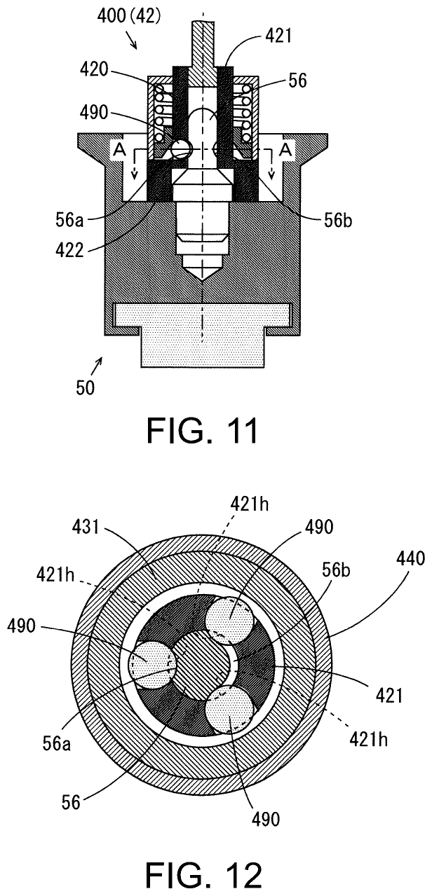

FIG. 11 is a vertical cross-sectional view showing a state where the brush device connecting portion 400 is holding the brush device 50, and FIG. 12 is a cross-sectional view taken along the line A-A of FIG. 11. As shown in FIG. 11 and FIG. 12, each steel ball 490 of the brush device connecting portion 400 has a part fitted into either the first groove 56a or the second groove 56b of the connected post 56 of the brush device 50. Thus, in a state where the brush device 50 is held by the brush device connecting portion 400, an engagement force caused by the elastic force of the spring 432 (FIG. 9) built into the brush device connecting portion 400 acts therebetween.

FIG. 13A and FIG. 13B are external perspective views for illustrating the operation when removing the brush device 50 held by the brush device connecting portion 400. In order to remove the brush device 50 from the brush device connecting portion 400, a removal structure 61 is required. The removal structure 61 is provided in the brush disposal part 60 of FIG. 1, as described above.

As shown in FIG. 13A, the removal structure 61 includes, for example, one or more (two in this example) plate-shaped members, and is disposed to be capable of abutting against the upper surface of the flange portion 55 of the brush device 50. When removing the brush device 50 from the brush device connecting portion 400, the flange portion 55 of the brush device 50 is arranged below the removal structure 61. Thereafter, as shown in FIG. 13B, the brush device connecting portion 400 is pulled upward with a certain force or more. At this time, inside the first cylindrical portion 421 of the brush device connecting portion 400, the first cylindrical portion 421 and the connected post 56 move relatively against the engagement force acting between the three steel balls 490 and the first groove 56a and the second groove 56b of the connected post 56. Thus, the brush device 50 is removed from the brush device connecting portion 400.

In the example of FIG. 13A and FIG. 13B, the removal structure 61 includes two plate-shaped members, but the disclosure is not limited thereto. The removal structure 61 may be formed of only one plate-shaped member as long as the removal structure 61 is capable of abutting against a part of the upper surface of the flange portion 55 and can fix the brush device 50 when removing the brush device 50.

### 6. Configuration and Operation of the Brush Storage Device 70

### (a) Outline of the Configuration of the Brush Storage Device 70

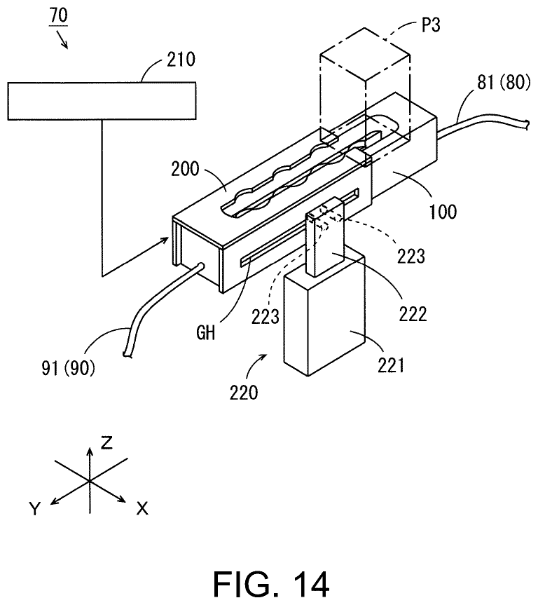

FIG. 14 is a view for illustrating the configuration of the brush storage device 70. FIG. 14 shows the configuration of the brush storage device 70 mainly in an external perspective view. As described above, the brush storage device 70 includes the brush storage tank 100, the brush support body 200, the storage brush horizontal drive part 210, and the storage brush lifting drive part 220.

As shown in FIG. 14, the brush storage tank 100 has a substantially rectangular parallelepiped shape that extends in one direction, and is disposed to extend along the Y direction. In this embodiment, the brush storage tank 100 is fixed at a predetermined position in the chamber CH. As described above, the brush storage tank 100 is configured to be capable of storing a plurality of brush devices 50. A piping 81 is connected to one end portion of the brush storage tank 100, and a piping 91 is connected to the other end portion of the brush storage tank 100. The piping 81 constitutes a part of the brush liquid supply system 80 of FIG. 1. The piping 91 constitutes a part of the brush liquid discharge system 90 of FIG. 1. The attachment position P3 in FIG. 1 is set near one end portion of the brush storage tank 100.

In the example of FIG. 14, the brush support body 200 is provided to cover a part of the brush storage tank 100 from above and both sides in the X direction. The brush support body 200 has a guide hole GH extending along the Y direction.

The storage brush lifting drive part 220 includes an air cylinder 221 and a lifting shaft 222. The air cylinder 221 is installed, for example, on the floor surface of the chamber CH in FIG. 1. The lifting shaft 222 is connected to a piston provided inside the air cylinder 221, and moves in the Z direction according to the pressure in the air cylinder 221. A pressure adjusting device (such as an electro-pneumatic regulator) (not shown) for adjusting the pressure in the air cylinder 221 is connected to the air cylinder 221.

Two connecting members 223 are attached to the upper end portion of the lifting shaft 222. The two connecting members 223 are shaft members such as screws, and are inserted into the guide holes GH of the brush support body 200. Thus, the lifting shaft 222 supports the brush support body 200 in a state where the brush support body 200 is movable along the direction of the guide hole GH (Y direction). Furthermore, the lifting shaft 222 adjusts the height position of the brush support body 200 in the Z direction to a desired height position.

The storage brush horizontal drive part 210 includes an actuator such as a motor or an air cylinder, and moves the brush support body 200 supported by the lifting shaft 222 in the Y direction. Thus, the storage brush horizontal drive part 210 adjusts the position of the brush support body 200 in the Y direction to a desired position.

### (b) Structure of the Brush Storage Tank 100

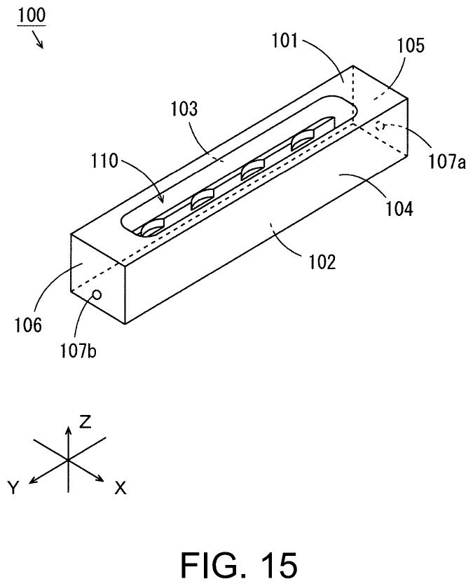

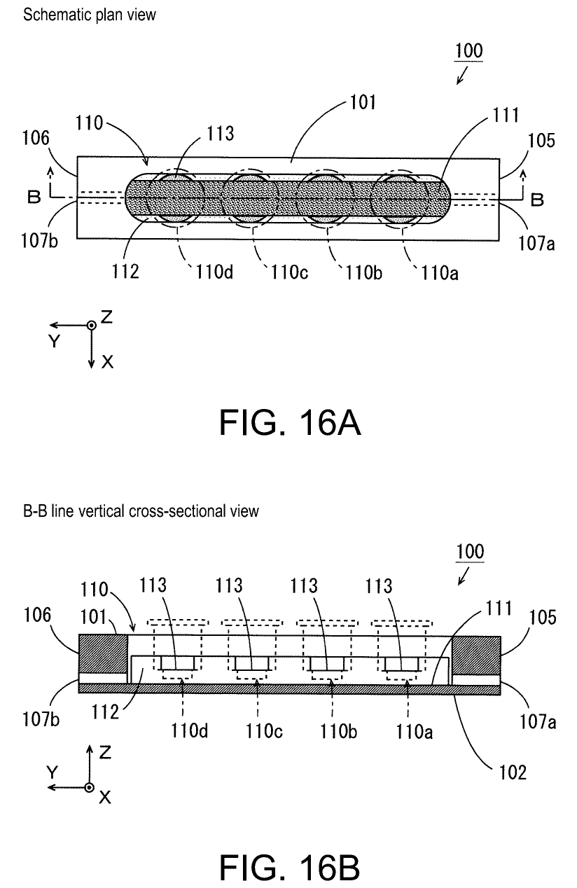

FIG. 15 is an external perspective view of the brush storage tank 100, and FIG. 16A and FIG. 16B are a schematic plan view and a vertical cross-sectional view of the brush storage tank 100 of FIG. 15. A schematic plan view of the brush storage tank 100 is shown in FIG. 16A, and a vertical cross-sectional view taken along the line B-B of FIG. 16A is shown in FIG. 16B.

As shown in FIG. 15, the brush storage tank 100 has an upper surface 101, a lower surface 102, a first side surface 103, a second side surface 104, a first end surface 105, and a second end surface 106. In this example, the first side surface 103 and the second side surface 104 are surfaces facing in opposite directions in the X direction. The first end surface 105 and the second end surface 106 are surfaces facing in opposite directions in the Y direction.

The upper surface 101 is formed with a brush storage hole 110. The brush storage hole 110 opens upward and is formed to extend from the vicinity of one end portion of the brush storage tank 100 to the vicinity of the other end portion. A liquid inlet 107a that is connected to the internal space of the brush storage hole 110 is formed in the first end surface 105. The piping 81 of FIG. 14 is connected to the liquid inlet 107a. A liquid outlet 107b that is connected to the internal space of the brush storage hole 110 is formed in the second end surface 106. The piping 91 of FIG. 14 is connected to the liquid outlet 107b.

As shown in FIG. 16A, the brush storage hole 110 is formed with a first storage space 110a, a second storage space 110b, a third storage space 110c, and a fourth storage space 110d that are capable of respectively accommodating a part of the brush device 50 of FIG. 6. The first storage space 110a, the second storage space 110b, the third storage space 110c, and the fourth storage space 110d are in communication with each other, and are arranged in this order at equal intervals in the direction from the first end surface 105 to the second end surface 106.

A storage hole bottom surface 111 that passes through the center of the brush storage hole 110 and extends in the Y direction is formed inside the brush storage hole 110. The storage hole bottom surface 111 is a band-shaped flat surface having a certain width in the X direction in plan view, and is perpendicular to the Z direction.

In addition, inside the brush storage hole 110, a pair of brush guide portions 112 extending in the Y direction are formed to sandwich the storage hole bottom surface 111 in the X direction. As shown in FIG. 16B, each brush guide portion 112 is formed to protrude upward by a certain height from the storage hole bottom surface 111.

In the upper half of the brush guide portion 112, a plurality of cutouts each having a circular arc shape (arch shape) in plan view are formed at positions where the plurality of storage spaces (110a to 110d) are formed. These cutouts are formed in accordance with the radius of curvature of the outer peripheral surface of the brush support body 52 of the brush device 50 of FIG. 6. Thus, the brush support body 52 of FIG. 6 is allowed to be inserted from above between the opposing cutouts of the pair of brush guide portions 112.

A brush support surface 113 facing upward is formed at the lower end portion of the plurality of cutouts formed in the brush guide portion 112. A plurality of brush support surfaces 113 formed in the pair of brush guide portions 112 are positioned on a common plane perpendicular to the Z direction. That is, the plurality of brush support surfaces 113 are formed at the same height position.

In FIG. 16A, in order to facilitate understanding of the positional relationship in the Z direction (relationship in height position) between the storage hole bottom surface 111, the upper end surface of the brush guide portion 112, and the plurality of brush support surfaces 113, three types of dot patterns with different densities are applied to the respective surfaces. The higher the density of the dot pattern applied to a surface, the lower the height position.

A pair of brush support surfaces 113 formed in a pair of cutouts facing each other in the X direction support the supported surface 53S (FIG. 7) of the brush support body 52 in a case where the brush support body 52 of FIG. 6 is inserted between the pair of cutouts. With such a configuration, it is possible to position and store the brush device 50 in a predetermined posture in each of the plurality of storage spaces (110a to 110d) in the brush storage hole 110 in the brush storage tank 100.

As the dimensions of each part of the brush storage tank 100, the distance between each brush support surface 113 and the storage hole bottom surface 111 in the Z direction is set to be larger than the distance between the supported surface 53S (FIG. 7) of the brush device 50 and the cleaning surface 51S (FIG. 7). Further, the distance between the upper surface 101 and each brush support surface 113 in the Z direction is set to be smaller than the distance between the flange portion 55 (FIG. 7) of the brush device 50 and the supported surface 53S (FIG. 7).

### (c) Structure of the Brush Support Body 200

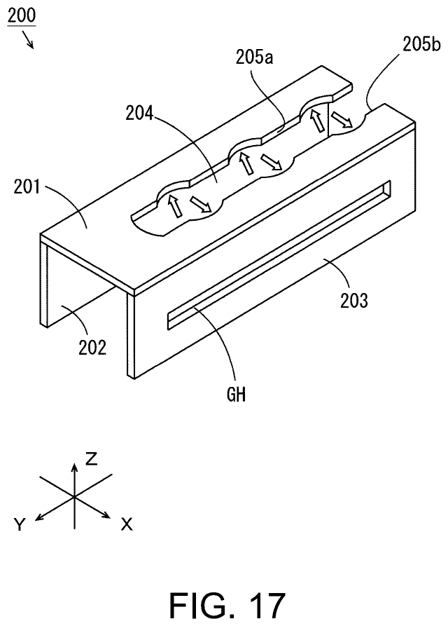

FIG. 17 is an external perspective view of the brush support body 200. As shown in FIG. 17, the brush support body 200 includes a support plate 201, a first side wall 202, and a second side wall 203. The support plate 201 has a substantially rectangular flat plate shape and extends in the Y direction. The length of the support plate 201 in the Y direction is shorter than the length of the brush storage tank 100 (FIG. 15) in the Y direction. On the other hand, the length of the support plate 201 in the X direction is slightly larger than the length of the brush storage tank 100 (FIG. 15) in the X direction.

The two long sides of the support plate 201 extend in parallel to the Y direction. The first side wall 202 and the second side wall 203 are each formed of a rectangular plate-shaped member, and are formed to extend downward from the two long sides of the support plate 201, respectively. The second side wall 203 is formed with the above-mentioned guide hole GH.

The support plate 201 is formed with a cutout 204 that extends in the Y direction from one end portion (one short side) in the Y direction to the vicinity of the other end portion (the other short side). The cutout 204 has a pair of opposing surfaces 205a and 205b that face each other in the X direction. As indicated by a plurality of hollow arrows in FIG. 17, each of the opposing surfaces 205a and 205b is formed with three recesses each having a circular arc shape in plan view. The three recesses on one opposing surface 205a respectively face the three recesses on the other opposing surface 205b. These recesses are formed to correspond to the radius of curvature of the outer peripheral surface of the brush support body 52 of the brush device 50 of FIG. 6. Thus, it is possible to insert the brush support body 52 of FIG. 6 between the opposing recesses of the pair of opposing surfaces 205a and 205b from above.

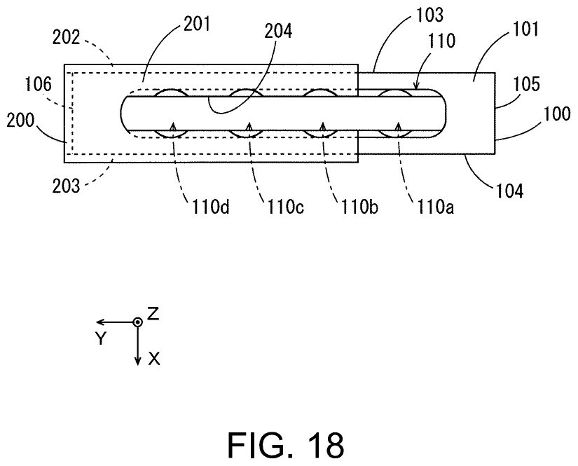

The brush support body 200 is provided, for example, to cover a part of the upper surface 101, the first side wall 202, and the second side wall 203 of the brush storage tank 100. FIG. 18 is a plan view showing an example of the configuration in which the brush support body 200 is provided to cover a part of the brush storage tank 100.

In the example of FIG. 18, the brush support body 200 is disposed at a position that is out of the first storage space 110a of the brush storage hole 110 in the Y direction and overlaps the second storage space 110b to the fourth storage space 110d of the brush storage hole 110 in the Y direction. Thus, the support plate 201 mainly covers the portion of the brush storage tank 100 from above, from approximately the central portion in the Y direction to the second end surface 106.

In this state, the three spaces between the three pairs of recesses arranged opposite to each other in the X direction in the cutout 204 of the brush support body 200 respectively overlap the three storage spaces (110b to 110d) of the brush storage tank 100 in plan view. Further, in the example of FIG. 18, a majority of the inner edge of the cutout 204 of the brush support body 200 is located slightly inward of the inner edge of the brush storage hole 110 of the brush storage tank 100 in plan view.

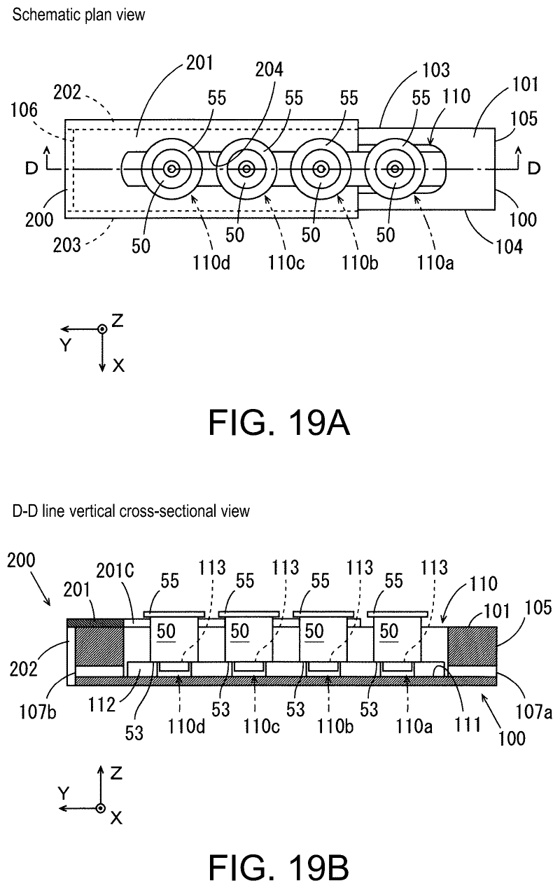

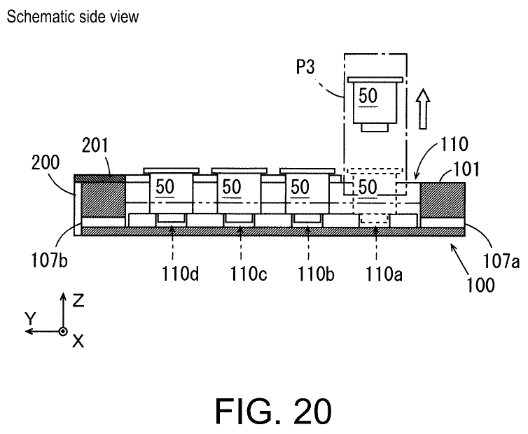

FIG. 19A and FIG. 19B are a schematic plan view and a vertical cross-sectional view showing a state where four brush devices 50 are stored in the brush storage tank 100 in the configuration of FIG. 18. A schematic plan view of the brush storage tank 100 and the brush support body 200 is shown in FIG. 19A, and a vertical cross-sectional view taken along the line D-D of FIG. 19A is shown in FIG. 19B. As shown in FIG. 19A, the outer diameter of the flange portion 55 of each brush device 50 is slightly larger than the width of the brush storage hole 110 in the X direction.

As shown in FIG. 19B, each brush device 50 is supported by the brush support surface 113 of the brush storage hole 110 in each storage space (110a to 110d). As described above, the distance in the Z direction between each brush support surface 113 and the storage hole bottom surface 111 is larger than the distance between the supported surface 53S (FIG. 7) and the cleaning surface 51S (FIG. 7) of the brush device 50. Thus, the cleaning surface 51S (FIG. 7) located at the lower end of each brush device 50 is held at a height position spaced apart from the storage hole bottom surface 111. In other words, in a state where each brush device 50 is stored in the brush storage tank 100, the supported surface 53S of the brush device 50 does not contact the storage hole bottom surface 111.

In addition, as described above, the distance in the Z direction between the upper surface 101 and each brush support surface 113 is smaller than the distance between the flange portion 55 (FIG. 7) of the brush device 50 and the supported surface 53S (FIG. 7). Thus, in a state where each brush device 50 is stored in the brush storage tank 100, the flange portion 55 located at the upper end of the brush device 50 is held at a height position a certain distance above the upper surface 101 of the brush storage tank 100. Therefore, a certain gap is formed between the flange portions 55 of the plurality of brush devices 50 and the upper surface 101 of the brush storage tank 100.

In a state where at least one brush device 50 is stored in the brush storage tank 100, the brush liquid is supplied into the brush storage tank 100 through the piping 81. Thus, a predetermined amount of brush liquid is stored in the brush storage tank 100. Further, a part of the brush liquid stored in the brush storage tank 100 is discharged through the piping 91. The supply amount and discharge amount of the brush liquid with respect to the brush storage tank 100 are adjusted so that the liquid level of the brush liquid stored in the brush storage tank 100 is above the brush 51 of the stored brush device 50. Thus, the brush device 50 stored in the brush storage tank 100 has the brush 51 immersed in the brush liquid and maintained in a wet state.

The thickness of the support plate 201 of the brush support body 200 is set to be smaller than the gap formed between the flange portions 55 of the plurality of brush devices 50 and the upper surface 101 of the brush storage tank 100. Thus, in the example of FIG. 19A and FIG. 19B, a part of the support plate 201 is located between the flange portions 55 of the three brush devices 50 and the upper surface 101 of the brush storage tank 100 at a position above the three storage spaces (110b, 110c, 110d).

### (d) Basic Operation of the Brush Storage Device 70

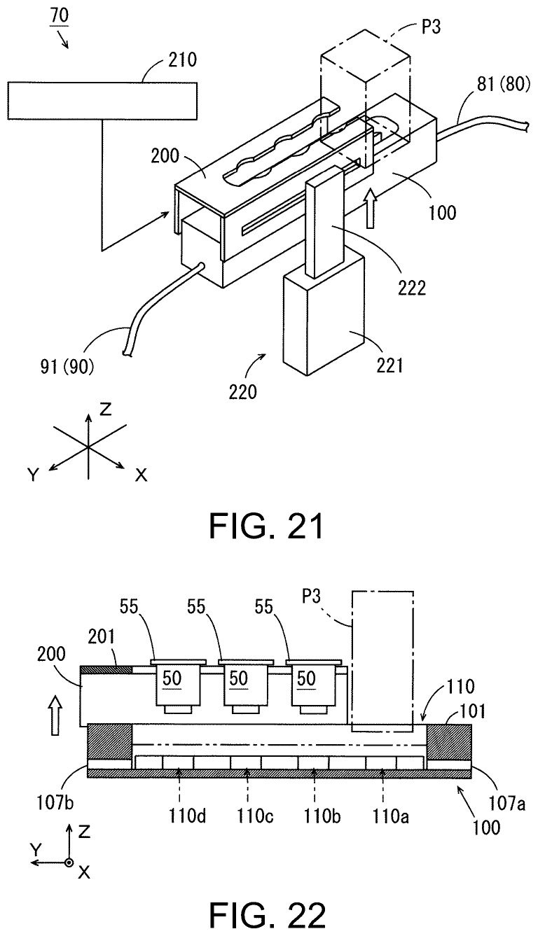

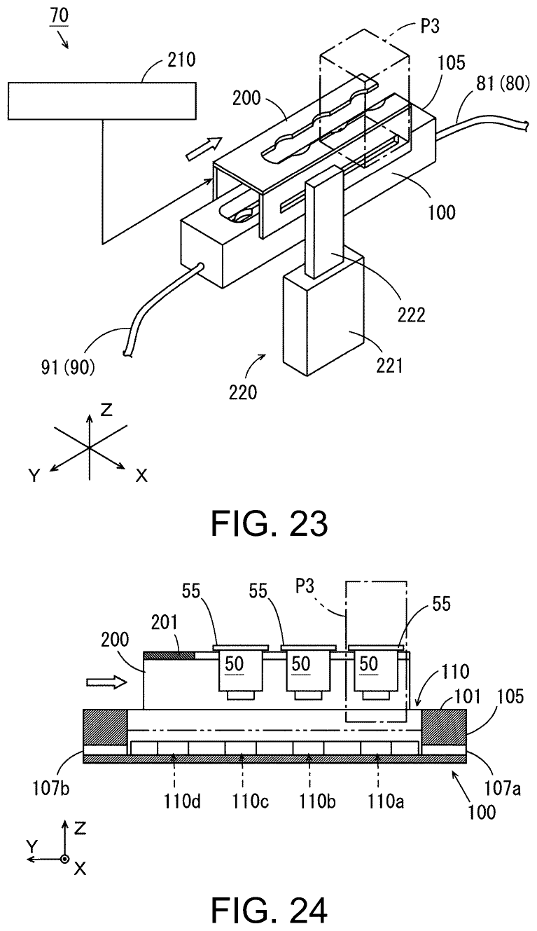

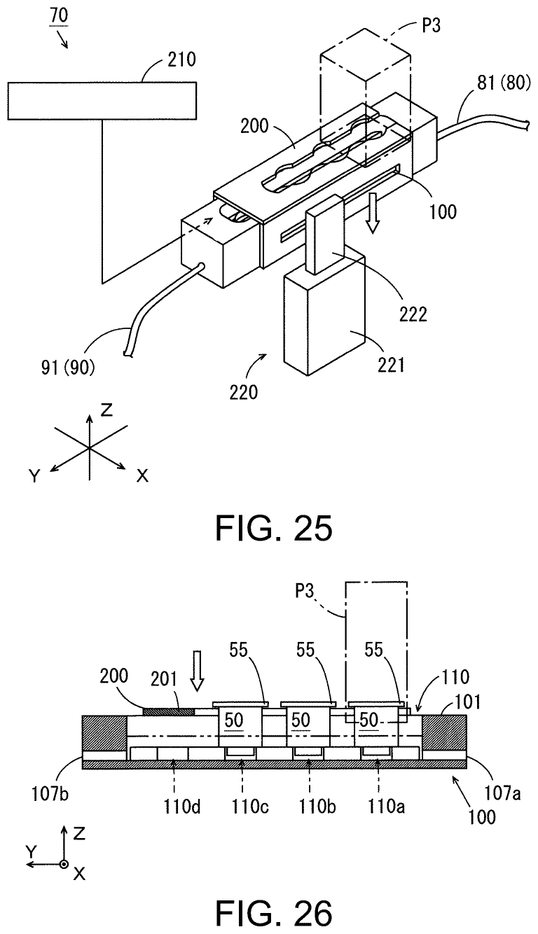

FIG. 20 to FIG. 26 are views for illustrating the basic operation of the brush storage device 70 accompanying the replacement process of the brush device 50. Hereinafter, the operation of each part of the brush storage device 70 will be described with reference to the vertical cross-sectional views of the brush storage tank 100 and the brush support body 200 and an external perspective view of the brush storage device 70. FIG. 20, FIG. 22, FIG. 24, and FIG. 26 among FIG. 20 to FIG. 26 show the vertical cross-sectional views of the brush storage tank 100 and the brush support body 200. These vertical cross-sectional views correspond to the vertical cross-sectional view of FIG. 19B. In addition, FIG. 21, FIG. 23, and FIG. 25 are external perspective views of the brush storage device 70. These vertical cross-sectional views correspond to the external perspective view of FIG. 14.

In the vertical cross-sectional views of FIG. 20, FIG. 22, FIG. 24, and FIG. 26, the liquid level of the brush liquid stored in the brush storage tank 100 is indicated by a two-dot chain line. In addition, in FIG. 21, FIG. 23, and FIG. 25, the plurality of brush devices 50 accommodated in the brush storage tank 100 are omitted from illustration in order to facilitate understanding of the operation of the brush storage device 70.

First, in the initial state, it is assumed that the brush storage device 70 is in the state of FIG. 14, and four brush devices 50 are stored in the four storage spaces (110a to 110d) of the brush storage hole 110 as shown in FIG. 19A and FIG. 19B. The replacement process of the brush device 50 is performed in this state. Thus, as indicated by the hollow arrow in FIG. 20, an unused brush device 50 stored in the first storage space 110a at the attachment position P3 is held by the brush holder 42 of FIG. 1 and pulled up from the brush storage tank 100.

In this embodiment, the attachment position P3 is set above the first storage space 110a of the brush storage tank 100. Therefore, when replacing the next brush device 50, a new unused brush device 50 is required to be stored in the first storage space 110a.

Thus, in a case where an unused brush device 50 is stored in the second storage space 110b of the brush storage tank 100 after the replacement process of the brush device 50, in the brush storage device 70, the following series of operations is performed before the next replacement process is performed.

First, as indicated by the hollow arrow in FIG. 21, the storage brush lifting drive part 220 operates to raise the brush support body 200 to a predetermined height with respect to the brush storage tank 100. At this time, as shown in FIG. 22, a part of the support plate 201 of the brush support body 200 supports the flange portion 55 of each brush device 50 so that all the remaining brush devices 50 stored in the brush storage tank 100 in the initial state are pulled upward. In this example, the three brush devices 50 stored in the second storage space 110b, the third storage space 110c, and the fourth storage space 110d are pulled up from the brush storage tank 100.

Here, the predetermined height to which the brush support body 200 rises is set to an extent that the lower end portion (cleaning surface 51S) of the brush device 50 supported by the brush support body 200 is positioned at least above the liquid level of the brush liquid stored in the brush storage tank 100. The predetermined height may be set to an extent that the brush device 50 supported by the brush support body 200 is positioned above the brush storage tank 100.

Next, as indicated by the hollow arrow in FIG. 23, the storage brush horizontal drive part 210 operates to move the brush support body 200 horizontally in the Y direction by a predetermined length with respect to the brush storage tank 100. More specifically, the brush support body 200 is moved in the Y direction by one pitch of the plurality of storage spaces (110a to 110d) aligned in the Y direction to approach the first end surface 105 of the brush storage tank 100. Thus, as shown in FIG. 24, the three brush devices 50 supported by the brush support body 200 are respectively arranged on the first storage space 110a, the second storage space 110b, and the third storage space 110c.

Next, as indicated by the hollow arrow in FIG. 25, the storage brush lifting drive part 220 operates to lower the brush support body 200 by a predetermined height with respect to the brush storage tank 100. At this time, as shown in FIG. 26, the three brush devices 50 supported by the brush support body 200 are accommodated in the brush storage hole 110. Thus, the three brush devices 50 are respectively stored in the first storage space 110a, the second storage space 110b, and the third storage space 110c. In this state, the brushes 51 of the three brush devices 50 are immersed in the brush liquid stored in the brush storage tank 100.

As described above, the brush support body 200 moves in the Z direction and the Y direction with respect to the brush storage tank 100, thereby changing the storage positions of one or more brush devices 50 stored in the brush storage tank 100. Then, when the brush device 50 stored in the first storage space 110a is removed from the brush storage tank 100 by the next replacement process of the brush device 50, the series of operations shown in FIG. 21 to FIG. 26 is repeated before the next replacement process is started.

In the substrate processing apparatus 1, work of recovering used brush devices 50 in the brush disposal part 60 and work of loading unused brush devices 50 into the brush storage tank 100 are carried out in a state where there is no brush device 50 in the brush storage tank 100.

### 7. Control System of the Substrate Processing Apparatus

The control system of the substrate processing apparatus 1 will be described together with the configuration of the controller 900 in FIG. 1. FIG. 27 is a block diagram showing the configuration of the control system of the substrate processing apparatus 1 of FIG. 1. As shown in FIG. 27, the controller 900 includes a CPU (Central Processing Unit) 901, a RAM (Random Access Memory) 902, a ROM (Read Only Memory) 903, and a storage device 904. The RAM 902 is used as a working area of the CPU 901. The ROM 903 stores a system program. The storage device 904 includes a storage medium such as a hard disk or a semiconductor memory, and stores a substrate cleaning program for performing the cleaning process on the substrate W, and a replacement processing program for performing the replacement process on the brush device 50.

The substrate cleaning program and the replacement processing program may be provided in a state of being stored in a recording medium such as a CD-ROM 909 and installed in the ROM 903 or the storage device 904. Alternatively, the substrate cleaning program and the replacement processing program may be distributed from a server outside the substrate processing apparatus 1 via a communication network and installed in the ROM 903 or the storage device 904.

The CPU 901 executes the substrate cleaning program and the replacement processing program to control the operation of each part of the substrate processing apparatus 1. Specifically, the controller 900 controls the substrate holding drive part 13. Thereby, the controller 900 causes the state of the plurality of holding pins 12 to transition from the released state to the holding state, thereby causing the substrate W carried into the substrate processing apparatus 1 to be held by the substrate holding device 10. Further, in order to unload the substrate W from the substrate processing apparatus 1, the controller 900 causes the state of the plurality of holding pins 12 to transition from the holding state to the released state. Furthermore, the controller 900 controls the substrate rotation drive part 14. Thereby, the controller 900 rotates the substrate W held by the substrate holding device 10 at a preset speed.

The controller 900 also controls the cup lifting drive part 22. Thereby, the controller 900 moves the cup body 21 in FIG. 1 between the cup upper position and the cup lower position during the cleaning process of the substrate W. The controller 900 also controls the fluid supply system 32. Thereby, the controller 900 supplies the cleaning liquid to the fluid nozzle 31 in FIG. 1 during the cleaning process of the substrate W.

In addition, the controller 900 controls the arm horizontal drive part 45 and the arm lifting drive part 46. Thereby, the controller 900 moves the brush arm 41 within the chamber CH during the cleaning process of the substrate W and during the replacement process of the brush device 50.

Further, the controller 900 controls the brush liquid supply system 80 and the brush liquid discharge system 90. Thereby, the controller 900 adjusts the supply amount of the brush liquid to the brush storage tank 100 and the discharge amount of the brush liquid from the brush storage tank 100 to maintain a state where the brush storage tank 100 stores a predetermined amount of brush liquid therein.

Furthermore, the controller 900 controls the storage brush horizontal drive part 210 and the storage brush lifting drive part 220. Thereby, the controller 900 moves the brush support body 200 in the Z direction and the Y direction so that the series of operations shown in FIG. 21 to FIG. 26 above is performed after the replacement process of the brush device 50 and before the next replacement process. Thus, an unused brush device 50 is stored in the first storage space 110a located below the attachment position P3.

### 8. Effects

(a) In the above-described substrate processing apparatus 1, the cleaning process of the substrate W is performed using one brush device 50 in a state where the one brush device 50 is held by the brush holder 42 of the brush arm 41. At this time, one or more unused brush devices 50 can be temporarily stored in the brush storage tank 100 of the brush storage device 70.

When one brush device 50 becomes contaminated or deteriorated to an extent that replacement is necessary, the one brush device 50 is removed from the brush holder 42 by the brush disposal part 60 at the removal position P2. Thereafter, the brush holder 42 is moved to the attachment position P3, and the brush device connecting portion 400 of the brush holder 42 is connected to the connected post 56 of an unused brush device 50 stored in the brush storage device 70. Thus, a new brush device 50 is held by the brush holder 42. In this manner, the replacement process of the brush device 50 is performed.

When the brush device 50 is used to clean the substrate W, the cleaning surface 51S of the brush 51 needs to be wetted to some extent. It takes a certain amount of time (for example, 15 minutes) to wet the cleaning surface 51S in a dry state to an extent suitable for cleaning the substrate W.

According to the above configuration, the cleaning surface 51S of the brush device 50 stored in the brush storage tank 100 of the brush storage device 70 is maintained in a state of being wetted by the brush liquid supplied to and stored in the brush storage tank 100. Therefore, there is no need to wet the cleaning surface 51S of the brush device 50 after the replacement process of the brush device 50 and before cleaning the substrate W with the new brush device 50 held by the brush holder 42. As a result, it is possible to shorten the time required from replacement of the brush device 50 to resumption of the cleaning process using the brush device 50.

(b) The above brush storage tank 100 is formed with a plurality of storage spaces (110a to 110d) aligned in one direction. Thus, a plurality of brush devices 50 can be respectively stored in the plurality of storage spaces (110a to 110d).

(c) In the above brush storage device 70, the attachment position P3 is set above the first storage space 110a. Further, in the brush storage device 70, the storage brush horizontal drive part 210 and the storage brush lifting drive part 220 operate after the replacement process of one brush device 50 is performed and before the next replacement process. Thus, the storage position of each of the brush devices 50 stored in the storage spaces (110b, 110c, and 110d) other than the first storage space 110a is sequentially changed to approach the first storage space 110a. Therefore, the replacement process of the brush device 50 can be smoothly performed at the preset attachment position P3.

(d) In the brush storage device 70, when changing the storage position, the brush device 50 stored in the brush storage tank 100 is pulled up to a height position above the liquid level of the brush liquid stored in the brush storage tank 100. Then, the brush device 50 is moved in the Y direction. In this case, the brush device 50 does not move in the horizontal direction while being in contact with the brush liquid stored in the brush storage tank 100. Therefore, disturbances in the liquid level of the brush liquid stored in the brush storage tank 100 are unlikely to occur. As a result, the brush liquid is prevented from leaking out of the brush storage tank 100.

(e) In the brush storage tank 100, four storage spaces (110a to 110d) are formed to be in communication with each other and aligned in one row within the horizontal plane from the first end surface 105 to the second end surface 106. The piping 81 of the brush liquid supply system 80 is connected to the first end surface 105. The piping 91 of the brush liquid discharge system 90 is connected to the second end surface 106. Thus, the brush liquid supplied from the piping 81 flows smoothly from one end portion of the brush storage tank 100 to the other end portion in the brush storage tank 100. Therefore, in a state where one or more brush devices 50 are stored in the brush storage tank 100, the cleaning surface 51S of each brush device 50 can be constantly immersed in the supplied fresh brush liquid.

(f) A part of the brush storage tank 100 (the part forming the first storage space 110a) overlaps, in plan view, the imaginary straight line L1 on which the brush holder 42 moves during the cleaning process of the substrate W. Further, the brush disposal part 60 also overlaps the imaginary straight line L1 in plan view. Thus, the standby position P1, the removal position P2, and the attachment position P3 are set on the imaginary straight line L1. In this case, during the replacement process of the brush device 50, the brush device 50 used after the cleaning process of the substrate W can be smoothly moved to the removal position P2. In addition, the brush holder 42 from which the brush device 50 has been removed can be smoothly moved to the attachment position P3.

(g) The brush device connecting portion 400 includes the spring 432. In the brush device connecting portion 400, an engagement force is generated between the brush device connecting portion 400 and the connected post 56 due to the spring 432 in a state where the connected post 56 is inserted into the first cylindrical portion 421. Thus, by inserting the connected post 56 into the first cylindrical portion 421 with a certain pressing force or more, the brush device 50 can be easily connected to the brush device connecting portion 400. In addition, by pulling out the connected post 56 inserted into the first cylindrical portion 421 with a certain tensile force or more, the brush device 50 connected to the brush device connecting portion 400 can be easily removed. In this manner, the configuration of the brush device connecting portion 400 and the connected post 56 of the brush device 50 makes it possible to attach and detach the brush device 50 to and from the brush device connecting portion 400 with a simple operation.

### 9. Other Embodiments

(a) In the brush storage device 70 according to the above embodiment, the brush arm 41 that holds the brush device 50 moves in the X direction in plan view. Therefore, in the above embodiment, the standby position P1, the removal position P2, and the attachment position P3 are set on the common imaginary straight line L1. However, the disclosure is not limited to the above example.

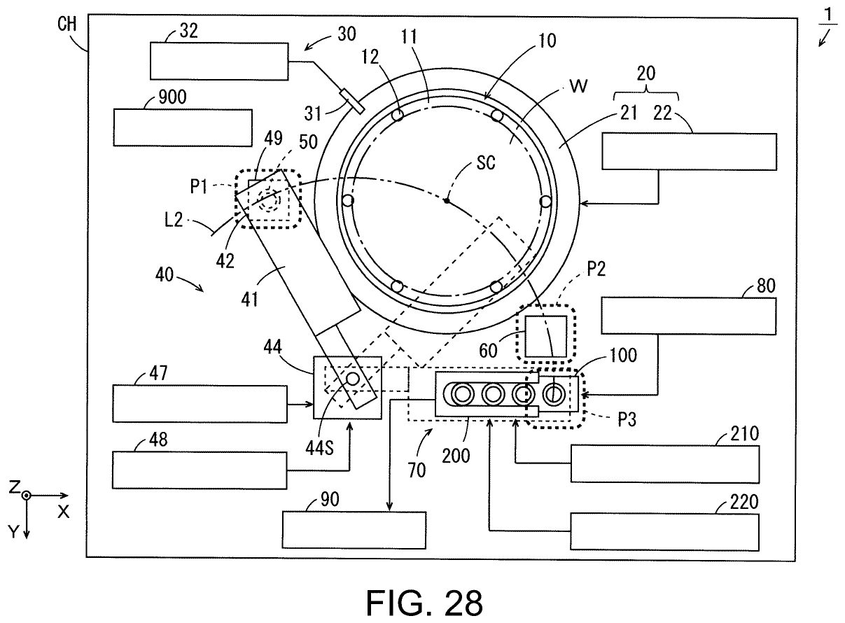

FIG. 28 is a schematic plan view of the substrate processing apparatus 1 according to another embodiment. The substrate processing apparatus 1 of FIG. 28 differs from the substrate processing apparatus 1 of FIG. 1 in the configuration of the brush arm device 40. The brush arm device 40 of FIG. 28 includes a brush arm 41, an arm support part 44, an arm rotation drive part 47, and an arm lifting drive part 48.

The arm support part 44 in this example is fixed onto the floor surface of the chamber CH at a position on a side of the substrate holding device 10. In addition, the arm support part 44 has a rotation shaft extending in the Z direction. The rotation shaft 44S thereof is provided to be capable of ascending and descending in the Z direction and rotatable around the axis of the rotation shaft 44S.

The arm rotation drive part 47 is, for example, a motor, and rotates the rotation shaft 44S around the axis of the rotation shaft 44S under the control of the controller 900. The arm lifting drive part 48 includes an actuator such as an air cylinder or a motor, and moves the rotation shaft 44S in the Z direction under the control of the controller 900.

The brush arm 41 has basically the same configuration as the brush arm 41 of FIG. 1, and one end portion of the brush arm 41 is attached to the rotation shaft 44S. The brush arm 41 extends in the horizontal direction from the rotation shaft 44S at a position above the substrate holding device 10 and the cup device 20. The other end portion (tip portion) of the brush arm 41 is configured as the brush holder 42 to be capable of holding and removing the brush device 50.

The arm rotation drive part 47 rotates the rotation shaft 44S so that, in plan view, the brush holder 42 moves on an imaginary circular arc L2 that passes through the rotation center SC of the spin base 11 based on the axis of the rotation shaft 44S. Thus, in this example, the standby pod 49, the substrate holding device 10, the brush disposal part 60, and the brush storage device 70 are arranged to be aligned on the imaginary circular arc L2 in this order. Thus, in the substrate processing apparatus 1, the standby position P1, the removal position P2, and the attachment position P3 are set to be arranged on the imaginary circular arc L2 in plan view.

In this case, when performing the replacement process of the brush device 50 after the cleaning process of the substrate W, the used brush device 50 can be smoothly moved to the removal position P2. Further, the brush holder 42 from which the brush device 50 has been removed can be smoothly moved to the attachment position P3.

(b) In the brush storage device 70 according to the above embodiment, the storage position of the brush device 50 in the brush storage tank 100 is changed by moving the brush support body 200 with respect to the brush storage tank 100, but the disclosure is not limited thereto. In the brush storage device 70, the position of the brush device 50 in the brush storage tank 100 may be changed by moving the brush storage tank 100 with respect to the brush support body 200.

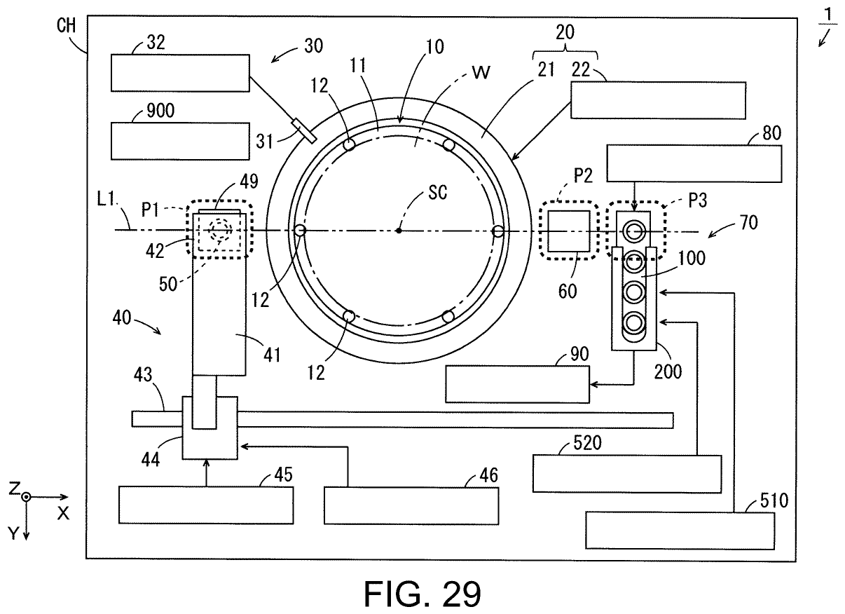

FIG. 29 is a schematic plan view of the substrate processing apparatus 1 according to yet another embodiment. The substrate processing apparatus 1 of FIG. 29 differs from the substrate processing apparatus 1 of FIG. 1 in the configuration of the brush storage device 70. The brush storage device 70 of FIG. 29 includes a tank horizontal drive part 510 and a tank lifting drive part 520 instead of the storage brush horizontal drive part 210 and the storage brush lifting drive part 220 of FIG. 1.

The tank horizontal drive part 510 includes an actuator such as a motor or an air cylinder, and is configured to be capable of adjusting the position of the brush storage tank 100 in the horizontal direction (in this example, the Y direction). The tank lifting drive part 520 includes an actuator such as a motor or an air cylinder, and is configured to be capable of adjusting the position of the brush storage tank 100 in the Z direction.

In the substrate processing apparatus 1 of this example, for example, in a case where the brush device 50 stored in the second storage space 110b is pulled out from the second storage space 110b and moved to the first storage space 110a, the brush support body 200 is maintained in a stationary state.

Specifically, in a state where one brush device 50 is stored in the second storage space 110b and supported by the brush support body 200, the tank lifting drive part 520 moves the brush storage tank 100 downward under the control of the controller 900. Thus, one brush device 50 is pulled out from the second storage space 110b while the brush support body 200 remains stationary.

Next, the tank horizontal drive part 510 moves the brush storage tank 100 in the Y direction under the control of the controller 900 so that the first storage space 110a is positioned below one brush device 50 held by the brush support body 200.

Thereafter, the tank lifting drive part 520 moves the brush storage tank 100 upward under the control of the controller 900. Thus, one brush device 50 held by the brush support body 200 is accommodated in the first storage space 110a. Finally, the tank horizontal drive part 510 moves the brush storage tank 100 in the Y direction under the control of the controller 900 so that the one brush device 50 stored in the first storage space 110a is positioned below the attachment position P3. Thus, similar to the above embodiment, in the brush storage device 70, the storage position of the brush device 50 in the brush storage tank 100 can be changed.

(c) The brush storage tank 100 according to the above embodiment is configured to be capable of holding four brush devices 50 simultaneously, but the disclosure is not limited thereto. The brush storage tank 100 may be configured to be capable of holding only two brush devices 50 simultaneously, may be configured to be capable of holding only three brush devices 50 simultaneously, or may be configured to be capable of holding five or more brush devices 50 simultaneously.

(d) In the brush storage device 70 according to the above embodiment, the brush 51 of the brush device 50 stored in the brush storage tank 100 is maintained in a wet state by storing the brush liquid in the brush storage tank 100, but the disclosure is not limited thereto. The brush storage device 70 may have a configuration that constantly discharges the brush liquid supplied from the brush liquid supply system 80 toward the brush 51 of the stored brush device 50. Even with such a configuration, an unused brush device 50 with the brush 51 kept wet can be stored in the chamber CH.

(e) The storage brush lifting drive part 220 according to the above embodiment is configured to be capable of raising and lowering the brush support body 200 by the air cylinder 221, but the disclosure is not limited thereto. The storage brush lifting drive part 220 may include another drive source such as a motor instead of the air cylinder 221, and may be configured to be capable of raising and lowering the brush support body 200 using the power of the another drive source.

(f) The brush storage hole 110 of the brush storage tank 100 according to the above embodiment is configured to be capable of accommodating a part of the brush device 50, but the brush storage hole 110 may be configured to be capable of accommodating the entire brush device 50.

(g) The brush holder 42 according to the above embodiment is configured to be attachable to and detachable from the connected post 56 of the brush device 50 by the brush device connecting portion 400 using the elastic force of the spring 432, but the disclosure is not limited thereto. The brush holder 42 may have an actuator that detachably holds the brush device 50. For example, instead of the above brush device connecting portion 400, the brush holder 42 may have two or more claws configured to be capable of gripping and releasing the connected post 56 of the brush device 50, and a drive source such as a motor for driving these claws.

(h) In the substrate processing apparatus 1 according to the above embodiment, the substrate holding device 10 has a so-called mechanical chuck type configuration in which a plurality of holding pins 12 abut against the outer peripheral end portion of the substrate W to hold the substrate W, but the disclosure is not limited thereto. The substrate holding device 10 may have a suction type configuration that holds the central portion of the lower surface of the substrate W by suction.

(i) The brush support body 200 according to the above embodiment may be configured to be capable of releasing the state of supporting one brush device 50 every time the operation of changing the storage position of the one brush device 50 from the second storage space 110b to the first storage space 110a is performed. In this case, the storage brush horizontal drive part 210 and the storage brush lifting drive part 220 of the brush storage device 70 may return the brush support body 200, which has released the state of supporting one brush device 50, to the position (original position) before the above-mentioned operation.

(j) In the brush storage device 70 according to the above embodiment, the attachment position P3 is set above the first storage space 110a. However, the disclosure is not limited thereto. The attachment position P3 may be set at a position other than above the brush storage tank 100. In this case, the brush storage device 70 may be configured to move the brush device 50 to the attachment position P3 by the brush storage tank 100 or the brush support body 200.

(k) The brush device 50 and the brush device connecting portion 400 according to the above embodiment are configured to be connectable to and detachable from each other in accordance with movement in the vertical direction. However, the disclosure is not limited thereto. The brush device 50 and the brush device connecting portion 400 may be configured to be connectable to and detachable from each other in accordance with movement in the horizontal direction. In addition, the brush storage tank 100 may have a configuration in which an opening is formed in a portion of one of the first side surface 103 and the second side surface 104. The opening provided on one side surface is formed in the upper portion of the one side surface so that a certain amount of cleaning liquid can be stored in the brush storage tank 100.

In a case where the brush device 50, the brush device connecting portion 400, and the brush storage tank 100 have the above-described configurations, the brush device connecting portion 400 moves toward the attachment position P3 as follows during the brush replacement process. First, the brush device connecting portion 400 has the height in the vertical direction adjusted by the arm lifting drive part 46 at a position near the brush storage tank 100, and is disposed to face the opening on one side surface of the brush storage tank 100 within the horizontal plane. Next, the brush device connecting portion 400 moves to the attachment position P3 in accordance with the movement in the horizontal direction caused by the arm horizontal drive part 45 to enter the inside of the brush storage tank 100 through the opening on one side surface. At this time, the brush device connecting portion 400 comes into contact with a part of the brush device 50 in the brush storage tank 100 so that the brush device 50 and the brush device connecting portion 400 are connected to each other.

Thus, with the above configuration, while a certain amount of cleaning liquid is stored in the brush storage tank 100, the brush device connecting portion 400 and the brush device 50 can be connected to each other through the opening formed on the first side surface 103 or the second side surface 104.

### 10. Correspondence Relationship Between Each Component of the Claims and Each Part of the Embodiment

An example of correspondence between each component of the claims and each element of the embodiment will be described below, but the disclosure is not limited to the following example. Various other elements having the configuration or function described in the claims may be used as each component of the claims.

In the above embodiment, the substrate processing apparatus 1 is an example of the substrate processing apparatus; the substrate holding device 10 is an example of the substrate holder; the connected post 56 is an example of the connected portion; the cleaning surface 51S is an example of the cleaning surface; the brush device 50 used in the cleaning process of the substrate W is an example of the first cleaning tool; the brush device 50 stored in the brush storage tank 100 is an example of the second cleaning tool; the brush device connecting portion 400 is an example of the connecting portion; and the brush holder 42 is an example of the cleaning tool holder.

Further, the brush storage device 70 is an example of the cleaning tool storage part; the arm horizontal drive part 45, the arm lifting drive parts 46 and 48, and the arm rotation drive part 47 are examples of the cleaning tool holder moving device; the brush liquid supply system 80 is an example of the processing liquid supply part; the brush liquid is an example of the processing liquid; and the controller 900 is an example of the controller.

In addition, the brush storage tank 100 is an example of the cleaning tool storage tank; the first storage space 110a, the second storage space 110b, the third storage space 110c, and the fourth storage space 110d are examples of a plurality of storage spaces; the first storage space 110a is an example of one storage space; and the brush support body 200, the storage brush horizontal drive part 210, the storage brush lifting drive part 220, the tank lifting drive part 520, and the tank horizontal drive part 510 are examples of the position changing part.

Further, the storage brush horizontal drive part 210 is an example of the horizontal moving part; the storage brush lifting drive part 220 is an example of the lifting moving part; the liquid inlet 107a is an example of the processing liquid inlet; the liquid outlet 107b is an example of the processing liquid outlet; the imaginary straight line L1 is an example of one straight line; and the imaginary circular arc L2 is an example of one circular arc.

Furthermore, as shown in FIG. 20, the height position of the brush support body 200 when the support plate 201 approaches the upper surface 101 of the brush storage tank 100 is an example of the lower height position; and as shown in FIG. 22, the height position of the brush support body 200 when the support plate 201 is separated from the upper surface 101 of the brush storage tank 100 by a distance equal to or greater than the height of the brush device 50 is an example of the upper height position.

### 11. Summary of the Embodiment

(1) A substrate processing apparatus according to the first aspect includes:
a substrate holder holding a substrate;
a first cleaning tool and a second cleaning tool each having a connected portion and a cleaning surface;
a cleaning tool holder including a connecting portion that is attachable to and detachable from the connected portions of the first cleaning tool and the second cleaning tool, and respectively holding the first cleaning tool and the second cleaning tool by connecting the connecting portion to the connected portion;
a cleaning tool storage part provided at a position spaced apart from the substrate held by the substrate holder and temporarily storing the second cleaning tool in a state where the first cleaning tool is held by the cleaning tool holder;
a cleaning tool holder moving device moving the cleaning tool holder so that the cleaning surface of the first cleaning tool or the second cleaning tool held by the cleaning tool holder comes into contact with the substrate, and moving the cleaning tool holder to the cleaning tool storage part;
a processing liquid supply part supplying a predetermined processing liquid to the cleaning tool storage part; and
a controller,
in which the controller controls the cleaning tool holder moving device in a state where the cleaning tool holder holds the first cleaning tool, to clean the substrate held by the substrate holder, and after the first cleaning tool used for cleaning the substrate is removed from the cleaning tool holder, controls the cleaning tool holder moving device to connect the connecting portion of the cleaning tool holder to the connected portion of the second cleaning tool temporarily stored in the cleaning tool storage part, and
the cleaning tool storage part is configured to maintain the cleaning surface of the second cleaning tool temporarily stored in a state of being wetted with the processing liquid supplied from the processing liquid supply part.

In the substrate processing apparatus, in a state where the first cleaning tool is held by the cleaning tool holder, the cleaning tool holder is moved so that the cleaning surface of the first cleaning tool comes into contact with the substrate held by the substrate holder. Thereby, the substrate is cleaned. At this time, the second cleaning tool is temporarily stored in the cleaning tool storage part.

When the first cleaning tool becomes contaminated or deteriorated to an extent that replacement is necessary, the first cleaning tool is removed from the cleaning tool holder. Thereafter, the cleaning tool holder is moved to the cleaning tool storage part, and the connecting portion of the cleaning tool holder is connected to the connected portion of the second cleaning tool stored in the cleaning tool storage part. In this manner, the cleaning tool held by the cleaning tool holder is replaced with a new cleaning tool.

When cleaning the substrate with the cleaning tool, the cleaning surface of the cleaning tool needs to be wetted to some extent. It takes a certain amount of time (for example, 15 minutes) to wet the cleaning surface in a dry state to an extent suitable for cleaning the substrate. According to the above configuration, the cleaning surface of the second cleaning tool stored in the cleaning tool storage part is maintained in a state of being wetted by the processing liquid supplied to the cleaning tool storage part. Therefore, there is no need to wet the cleaning surface of the second cleaning tool after the cleaning tool held by the cleaning tool holder is replaced from the first cleaning tool to the second cleaning tool and before cleaning the substrate with the new second cleaning tool. As a result, it is possible to shorten the time required from replacement of the cleaning tool to resumption of the cleaning process using the cleaning tool.

(2) In the substrate processing apparatus according to the first aspect,
the cleaning tool storage part may include a cleaning tool storage tank having a storage space that opens upward and is capable of storing the second cleaning tool by accommodating at least a part of the second cleaning tool including the cleaning surface, and the cleaning tool storage tank may be configured to be capable of storing the processing liquid supplied from the processing liquid supply part in the storage space.

In this case, the cleaning surface of the second cleaning tool can be immersed in the processing liquid stored in the storage space by storing the second cleaning tool in the storage space of the cleaning tool storage tank. Thus, the cleaning surface of the second cleaning tool stored in the cleaning tool storage part can be kept wet with a simple configuration.

(3) In the substrate processing apparatus according to the second aspect,
the cleaning tool storage tank may have a plurality of the storage spaces, and may be configured to be capable of connecting the connecting portion of the cleaning tool holder to the connected portion of the second cleaning tool in a state where the second cleaning tool is stored in one storage space among the plurality of storage spaces,
the cleaning tool storage part may further include a position changing part that changes a positional relationship between the second cleaning tool and the cleaning tool storage tank by moving at least one of the second cleaning tool and the cleaning tool storage tank, and
the controller may control the position changing part in a state where the second cleaning tool is stored in another storage space among the plurality of storage spaces, to move the second cleaning tool held in the another storage space from the another storage space to the one storage space.

In this case, a plurality of cleaning tools including the second cleaning tool can be stored in the plurality of storage spaces. Furthermore, according to the above configuration, a position above one storage space of the cleaning tool storage tank can be set as the attachment position for attaching the second cleaning tool to the cleaning tool holder.

(4) In the substrate processing apparatus according to the third aspect,
the position changing part may include:
a horizontal moving part moving the second cleaning tool in a horizontal direction; and
a lifting moving part moving the second cleaning tool in an up-down direction.

In this case, the second cleaning tool moves in the horizontal direction and the up-down direction among the plurality of storage spaces.

(5) In the substrate processing apparatus according to the fourth aspect,
the lifting moving part may be configured to be capable of moving the second cleaning tool between a lower height position when the second cleaning tool is stored in any one of the plurality of storage spaces, and an upper height position when the second cleaning tool is above a liquid level of the processing liquid stored in the cleaning tool storage tank, and
in a case of moving the second cleaning tool held in the another storage space to the one storage space, the controller may control the horizontal moving part and the lifting moving part to raise the second cleaning tool held in the another storage space from the lower height position to the upper height position, move the second cleaning tool at the upper height position in the horizontal direction to a position above the one storage space, and lower the second cleaning tool that has been moved to the position above the storage space from the upper height position to the lower height position.

In this case, the second cleaning tool does not move in the horizontal direction while being in contact with the processing liquid stored in the cleaning tool storage tank. Therefore, disturbances in the liquid level of the processing liquid stored in the cleaning tool storage tank are unlikely to occur. As a result, the processing liquid is prevented from leaking out of the cleaning tool storage tank.

(6) In the substrate processing apparatus according to any one of the third to fifth aspects,
the plurality of storage spaces may be formed to be in communication with each other and aligned in one row within a horizontal plane, and
the cleaning tool storage tank may include:
a processing liquid inlet that introduces the processing liquid into the storage space located at one end portion of the plurality of storage spaces; and
a processing liquid outlet that discharges the processing liquid stored in the plurality of storage spaces from the storage space located at the other end portion of the plurality of storage spaces.

In this case, the processing liquid can be smoothly circulated among the plurality of storage spaces. Therefore, in a state where the second cleaning tool is stored in the cleaning tool storage tank, the cleaning surface of the second cleaning tool can be constantly immersed in the supplied fresh processing liquid.

(7) In the substrate processing apparatus according to any one of the third to sixth aspects,
the cleaning tool holder moving device may move the cleaning tool holder to trace one straight line or one circular arc passing through a center of the substrate in a plan view when cleaning the substrate with the first cleaning tool or the second cleaning tool, and
the one storage space of the cleaning tool storage tank may overlap the one straight line or the one circular arc in the plan view.

In this case, after cleaning the substrate with the first cleaning tool, the cleaning tool holder, from which the first cleaning tool has been removed, can be smoothly moved to above one storage space in the cleaning tool storage tank.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

What is claimed is:

1. A substrate processing apparatus, comprising:
a substrate holder holding a substrate;
a first cleaning tool and a second cleaning tool each having a connected portion and a cleaning surface;
a cleaning tool holder comprising a connecting portion that is attachable to and detachable from the connected portions of the first cleaning tool and the second cleaning tool, and respectively holding the first cleaning tool and the second cleaning tool by connecting the connecting portion to the connected portion;
a cleaning tool storage part provided at a position spaced apart from the substrate held by the substrate holder and temporarily storing the second cleaning tool in a state where the first cleaning tool is held by the cleaning tool holder;
a cleaning tool holder moving device moving the cleaning tool holder so that the cleaning surface of the first cleaning tool or the second cleaning tool held by the cleaning tool holder comes into contact with the substrate, and moving the cleaning tool holder to the cleaning tool storage part;
a processing liquid supply part supplying a predetermined processing liquid to the cleaning tool storage part; and
a controller,
wherein the controller controls the cleaning tool holder moving device in a state where the cleaning tool holder holds the first cleaning tool, to clean the substrate held by the substrate holder, and after the first cleaning tool used for cleaning the substrate is removed from the cleaning tool holder, controls the cleaning tool holder moving device to connect the connecting portion of the cleaning tool holder to the connected portion of the second cleaning tool temporarily stored in the cleaning tool storage part, and
the cleaning tool storage part is configured to maintain the cleaning surface of the second cleaning tool temporarily stored in a state of being wetted with the processing liquid supplied from the processing liquid supply part.

2. The substrate processing apparatus according to claim 1, wherein the cleaning tool storage part comprises a cleaning tool storage tank having a storage space that opens upward and is capable of storing the second cleaning tool by accommodating at least a part of the second cleaning tool including the cleaning surface, and
the cleaning tool storage tank is configured to be capable of storing the processing liquid supplied from the processing liquid supply part in the storage space.

3. The substrate processing apparatus according to claim 2, wherein the cleaning tool storage tank has a plurality of the storage spaces, and is configured to be capable of connecting the connecting portion of the cleaning tool holder to the connected portion of the second cleaning tool in a state where the second cleaning tool is stored in one storage space among the plurality of storage spaces,
the cleaning tool storage part further comprises a position changing part that changes a positional relationship between the second cleaning tool and the cleaning tool storage tank by moving at least one of the second cleaning tool and the cleaning tool storage tank, and
the controller controls the position changing part in a state where the second cleaning tool is stored in another storage space among the plurality of storage spaces, to move the second cleaning tool held in the another storage space from the another storage space to the one storage space.

4. The substrate processing apparatus according to claim 3, wherein the position changing part comprises:
a horizontal moving part moving the second cleaning tool in a horizontal direction; and
a lifting moving part moving the second cleaning tool in an up-down direction.

5. The substrate processing apparatus according to claim 4, wherein the lifting moving part is configured to be capable of moving the second cleaning tool between a lower height position when the second cleaning tool is stored in any one of the plurality of storage spaces, and an upper height position when the second cleaning tool is above a liquid level of the processing liquid stored in the cleaning tool storage tank, and
in a case of moving the second cleaning tool held in the another storage space to the one storage space, the controller controls the horizontal moving part and the lifting moving part to raise the second cleaning tool held in the another storage space from the lower height position to the upper height position, move the second cleaning tool at the upper height position in the horizontal direction to a position above the one storage space, and lower the second cleaning tool that has been moved to the position above the storage space from the upper height position to the lower height position.

6. The substrate processing apparatus according to claim 3, wherein the plurality of storage spaces are formed to be in communication with each other and aligned in one row within a horizontal plane, and
the cleaning tool storage tank comprises:
a processing liquid inlet that introduces the processing liquid into the storage space located at one end portion of the plurality of storage spaces; and
a processing liquid outlet that discharges the processing liquid stored in the plurality of storage spaces from the storage space located at the other end portion of the plurality of storage spaces.

7. The substrate processing apparatus according to claim 3, wherein the cleaning tool holder moving device moves the cleaning tool holder to trace one straight line or one circular arc passing through a center of the substrate in a plan view when cleaning the substrate with the first cleaning tool or the second cleaning tool, and
the one storage space of the cleaning tool storage tank overlaps the one straight line or the one circular arc in the plan view.
